(19) United States
(12) Patent Application Publication
(10) Pub. No.: US 2026/0164776 A1
(43) Pub. Date: Jun. 11, 2026

(54) TRANSISTOR STRUCTURE

(71) Applicant: Invention and Collaboration Laboratory, Inc., Taipei City (TW)

(72) Inventors: Chao-Chun Lu, Taipei City (TW); Wen-Hsien Tu, Hsinchu (TW)

(73) Assignee: Invention and Collaboration Laboratory, Inc., Taipei City (TW)

(21) Appl. No.: 19/375,136

(22) Filed: Oct. 30, 2025

Related U.S. Application Data
(60) Provisional application No. 63/730,907, filed on Dec. 11, 2024.
(60) Provisional application No. 63/782,015, filed on Apr. 2, 2025.
(60) Provisional application No. 63/862,045, filed on Aug. 12, 2025.

(51) Int. Cl. H10D 84/83; H10D 30/00; H10D 30/01; H10D 30/43; H10D 30/60; H10D 62/10; H10D 62/13; H10D 84/01; H10D 84/85

(52) U.S. Cl. CPC H10D 84/832; H10D 30/43; H10D 30/502; H10D 30/601; H10D 62/121; H10D 62/151; H10D 84/851; H10D 30/014; H10D 30/0191; H10D 30/0227; H10D 84/0151

(57) ABSTRACT

A transistor structure includes a semiconductor substrate, a shallow trench isolation (STI) region, a gate region, a first conductive region and an inter-layer dielectric (ILD) portion. The semiconductor substrate has a three-dimensional (3D) semiconductor body and a horizontal semiconductor surface. The shallow trench isolation (STI) region surrounds a lower portion of the 3D semiconductor body. The gate region crosses over an upper portion of the 3D semiconductor body. The first conductive region is electrically coupled to a channel region within the upper portion of the 3D semiconductor body. The inter-layer dielectric (ILD) portion is over the STI portion and surrounds the first conductive region. A high thermal conductivity (HTC) material is deposited within the STI portion and/or the ILD portion, and a thermal conductivity of the HTC material is higher than that of SiO₂.

### CROSS REFERENCE TO RELATED APPLICATIONS

This application claims the benefit of U.S. Provisional Application No. 63/730,907, filed on Dec. 11, 2024. Further, this application claims the benefit of U.S. Provisional Application No. 63/782,015, filed on Apr. 2, 2025. Further, this application claims the benefit of U.S. Provisional Application No. 63/862,045, filed on Aug. 12, 2025. The contents of these applications are incorporated herein by reference.

### BACKGROUND OF THE INVENTION

### 1. Field of the Invention

The present invention relates to a transistor structure, and particularly to a transistor structure which can have heat dissipation path to dissipate heat generated from S/D junctions (source region and drain region) of the transistor structure.

### 2. Description of the Prior Art

Since design guidelines of scaling down all dimensions of a metal-oxide-semiconductor field-effect transistor (MOSFET) have been disclosed in the paper published by R. Dennard, et al. in 1974, how to shrink a size of a transistor is a major technology demand which has reduced the minimum physical feature size on a linear dimension of a silicon wafer.

Nowadays, the silicon technology especially its basic element MOSFET is being scaled down fast from 28 nm to 1.8 nm (in research and design), but how to scale down the MOSFET depends on sophisticated technologies such as using very expensive lithography equipment (e.g. extreme ultraviolet lithography (EUV), deep ultraviolet lithography (DUV), etc.), multiple expensive masks, complicated etching technologies, and exhausted contact opening as well as metallization technologies, etc. Nowadays, GAA (gate-All-Around) transistor structure is well-utilized in technology node of 1.6˜3 nm. for conventional contact hole mask used in the semiconductor manufacture process, there are lots of contact mask patterns each of which is rectangle-like or square-like shape, and those contact mask patterns will be reproduced based on photolithographic process to define the two dimension lengths of the contact hole openings for connecting to the gate/drain/source of the transistor. As the shrink of the minimum feature size or technology process node to some nanometer scale, those expensive EUV equipment, complicated etching technologies, exhausted contact openings of the contact mask and extreme tight design rules are required to avoid or to accommodate the misalignments between those contact holes and the gate/drain/source of the transistor. Therefore, the manufacture cost of those transistors are dramatically increased and the area size of those transistors could not be shrunk proportionally when the minimum feature size or the technology process node is shrunk.

This present invention proposes a new transistor (such as GAA, CFET, etc.) structure which can have heat dissipation path to dissipate heat generated from S/D junctions (source region and drain region) of the transistor structure. Additionally, the new transistor could be with a first metal interconnection (metal-1 layer) directly connecting gate, source and/or drain regions through self-aligned miniaturized contacts without using a conventional contact-hole-opening mask and/or a metal-0 translation layer for metal-1 connections.

### SUMMARY OF THE INVENTION

An embodiment of the present invention provides a transistor structure. The transistor structure includes a semiconductor substrate, a shallow trench isolation (STI) region, a gate region, a first conductive region and an inter-layer dielectric (ILD) portion. The semiconductor substrate has a three-dimensional (3D) semiconductor body and a horizontal semiconductor surface. The shallow trench isolation (STI) region surrounds a lower portion of the 3D semiconductor body. The gate region crosses over an upper portion of the 3D semiconductor body. The first conductive region is electrically coupled to a channel region within the upper portion of the 3D semiconductor body. The inter-layer dielectric (ILD) portion is over the STI portion and surrounds the first conductive region. A high thermal conductivity (HTC) material is deposited within the STI portion and/or the ILD portion, and a thermal conductivity of the HTC material is higher than that of SiO₂.

According to one aspect of the present invention, the HTC material is within the ILD portion and surrounds at least three sidewalls of the first conductive region.

According to one aspect of the present invention, the HTC material is within the ILD portion, a top surface of the ILD portion is higher than a top surface of the first conductive region, and a top surface of the HTC material is close to the top surface of the first conductive region.

According to one aspect of the present invention, the HTC material is within the ILD portion, and the ILD portion further comprises a dielectric isolation layer surrounding the HTC material.

According to one aspect of the present invention, the HTC material is within the ILD portion, and the HTC material includes Si, and a grain size of the Si is greater than 0.5 um.

According to one aspect of the present invention, the HTC material is within the ILD portion, the HTC material includes large grain Si, and the ILD portion further comprises an oxide layer surrounding the large grain Si.

According to one aspect of the present invention, the HTC material is within the STI portion, a top surface of the STI portion is close to a bottom surface of the first conductive region, and the STI portion further comprises a dielectric isolation layer surrounding the HTC material.

According to one aspect of the present invention, a shape of the first conductive region is a diamond shape.

According to one aspect of the present invention, the HTC material includes Si, and a grain size of the Si is greater than 0.5 um.

According to one aspect of the present invention, the HTC material includes large grain Si, and the ILD portion further comprises an oxide layer surrounding the large grain Si.

According to one aspect of the present invention, both the STI portion and the ILD portion comprises the HTC material, and there is a dielectric isolation layer between the HTC material of the STI portion and the HTC material of the ILD portion.

According to one aspect of the present invention, the HTC material of the ILD portion and surrounds at least three sidewalls of the first conductive region, a top surface of the HTC material of the STI portion is close to a bottom surface of the first conductive region, and a shape of the first conductive region is a diamond shape.

According to one aspect of the present invention, the transistor structure is a FinFET, GAA, or CFET transistor structure.

Another embodiment of the present invention provides a transistor structure. The transistor structure includes a semiconductor substrate, a channel region, a gate region, a composite shallow trench isolation (STI) region and a first conductive region. The semiconductor substrate has an active region and a horizontal semiconductor surface. The channel region is within the active region. The gate region crosses over the active region and surrounds the channel region, the gate region including a gate extension portion. The composite shallow trench isolation (STI) region surrounds the active region, wherein the composite STI region includes a first high thermal conductivity (HTC) material and a dielectric isolation layer surrounds the HTC material, and a thermal conductivity of the first HTC material is higher than that of SiO₂. The first conductive region is electrically coupled to the channel region. A top surface of the composite STI region is higher than the horizontal semiconductor surface.

According to one aspect of the present invention, the first HTC material surrounds at least three sides of the first conductive region.

According to one aspect of the present invention, the composite STI region is next to the first conductive region, and a top surface of the first HTC material close to or higher than a top surface of the first conductive region.

According to one aspect of the present invention, the channel region includes multiple semiconductor sheets; the first conductive region includes a lightly doped region derived from the multiple semiconductor sheets, a highly doped region abutting to a sidewall of the lightly doped region, and a core metal column at least abutting to a sidewall of the highly doped region; and the transistor structure further includes a trench, a localized isolation region and a metal connection layer. The trench is under the horizontal semiconductor surface of the semiconductor substrate to accommodate the lightly doped region, the heavily doped region and the core metal column. The localized isolation region is under bottom surfaces of the heavily doped region and the core metal column. The metal connection layer covers top surfaces of the heavily doped region and the core metal column.

According to one aspect of the present invention, the transistor structure is a GAA or CFET transistor structure.

According to one aspect of the present invention, a bottom of the gate extension portion is lower than a bottom of the first conductive region.

According to one aspect of the present invention, a first concave is formed to reveal the first conductive region, a second concave is formed over the gate extension portion to reveal the gate conductive region; and a metal connection layer is formed to fill both the first concave and the second concave and the metal connection layer is extended from the first concave to the second concave.

According to one aspect of the present invention, sidewalls of the first conductive region is limited by the composite STI region, and the limited sidewalls of the first conductive region is vertical or substantially vertical.

According to one aspect of the present invention, the HTC material comprises Si, and a grain size of the Si is greater than 0.3 um.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating a top view of a transistor according to an embodiment of the present invention.

FIG. 1B is a diagram illustrating a similar design like the NuGAAT of FIG. 1A according to another embodiment of the present invention.

FIG. 2A is a flowchart illustrating a manufacturing process of a NuGAAT according to another embodiment of the present invention.

FIG. 2B, FIG. 2C, FIG. 2D, FIG. 2E, FIG. 2F are diagrams illustrating FIG. 2A.

FIG. 3 is a diagram illustrating a top view and a cross-section view along an X direction after the pad-nitride layer and the pad-oxide layer are deposited and the STI is formed.

FIG. 4 is a diagram illustrating the pad-oxide layer and the pad-nitride layer being removed, a dielectric insulator being formed over the HSS, and using a photolithographic mask to define true gate regions and dummy gate regions of the NuGAAT.

FIG. 5A is a diagram illustrating depositing and etching back a nitride spacer, and then a gate material and a nitride layer being deposited above the HSS to form the true gate (TG) and the dummy shield gates (DSG) of the NuGAAT.

FIG. 5B is a diagram illustrating a top view of FIG. 5A.

FIG. 6A is a diagram illustrating the well-designed gate mask layer being deposited and patterned.

FIG. 6B is a diagram illustrating a top view of FIG. 6A.

FIG. 7A is a diagram illustrating the dummy shield gate (DSG), the nitride layer, the dielectric insulator, the superlattice Si/SiGe structure and the p-type substrate corresponding to the DSG being removed by the etching technique.

FIG. 7B is a diagram illustrating a top view of FIG. 7A.

FIG. 8 is a diagram illustrating the gate mask layer being removed, the SOD being etched, and a STI-oxide-2 being deposited.

FIG. 9, FIG. 10, FIG. 11, FIG. 12 are diagrams illustrating misalignment behavior between a position of the true gate (TG) and a position of the dummy shield gate (DSG).

FIG. 13 is a diagram illustrating removing the superlattice Si/SiGe structure for the source/drain regions, etching a part of each exposed SiGe layer of the superlattice Si/SiGe structure, and then forming an inner spacer on the SiGe layer of the superlattice Si/SiGe structure.

FIG. 14 is a diagram illustrating growing oxide-3B layer, then forming a SiOCN layer on a top of the oxide-3B layer, then using a selective growth technique to form n-type LDD region, n+ doped source region and n+ doped drain region, and finally deposit and CMP a dielectric film (SOD).

FIG. 15 is a diagram illustrating removing previous temporary gate structure and the SiGe layers of the superlattice Si/SiGe structure, then forming the gate structure of the NuGAAT, and then removing the dielectric film (SOD).

FIG. 16A is a diagram illustrating forming the composite spacer surrounding the TG.

FIG. 16B is a diagram illustrating a top view of FIG. 16A and multiple NuGAATs in horizontal direction.

FIG. 17 is a diagram illustrating the thermal dissipation effect by 3D technology computer aided design (TCAD).

FIG. 18A is a diagram illustrating depositing a SOD.

FIG. 18B is a diagram illustrating a top view of FIG. 18A and multiple NuGAATs in horizontal direction.

FIG. 19 is a diagram illustrating the photo resistance being deposited.

FIG. 20A, FIG. 20B are diagrams illustrating two possible scenarios of FIG. 19.

FIG. 21 is a diagram illustrating removing the hardmask layer within the GROC being removed to expose the true gate (TG).

FIG. 22A is a diagram illustrating removing the photoresist layer, removing the SOD, and then forming a metal-1 layer.

FIG. 22B is a diagram illustrating a top view of the structure of the NuGAAT shown in FIG. 22A.

FIG. 23 is a top view of another embodiment with separate multiple NuGAATs extending in horizontal direction.

FIG. 24A, FIG. 24B are diagrams illustrating both cross-section and top view of the NuGAAT at the stage of forming contact openings on the source region and the drain region, respectively.

FIG. 25 shows a top view of another NuGAAT with a layout design using separate multiple NuGAATs for drain regions.

FIG. 26A, FIG. 26B show both cross-section and top view of the NuGAAT formation at the stage of forming contact openings on the drain regions and the gate structure for the extension connection crossover to the drain regions, respectively.

FIG. 27 is a diagram illustrating the NuGAAT structure with the 3D modeling structure.

FIG. 28 is a diagram illustrating the NuCFET (new complementary field-effect transistor) structure with the 3D modeling structure.

FIG. 29 is a diagram illustrating the advanced semiconductor manufacturing process for option A shown in FIG. 32(b).

FIG. 30 is a diagram illustrating the 3D modeling structure of conventional GAAT structure.

FIG. 31 is diagram illustrating a 3D perspective view for FIG. 32(b).

FIG. 32 is a diagram illustrating the heat dissipation paths of the conventional GAAT structure and the NuGAAT structure.

FIG. 33 is a diagram illustrating the 3D modeling structure of conventional CFET structure.

FIG. 34 is diagram illustrating a 3D perspective view for FIG. 35(b).

FIG. 35 is a diagram illustrating the heat dissipation paths of the conventional CFET structure and the NuCFET structure.

### DETAILED DESCRIPTION

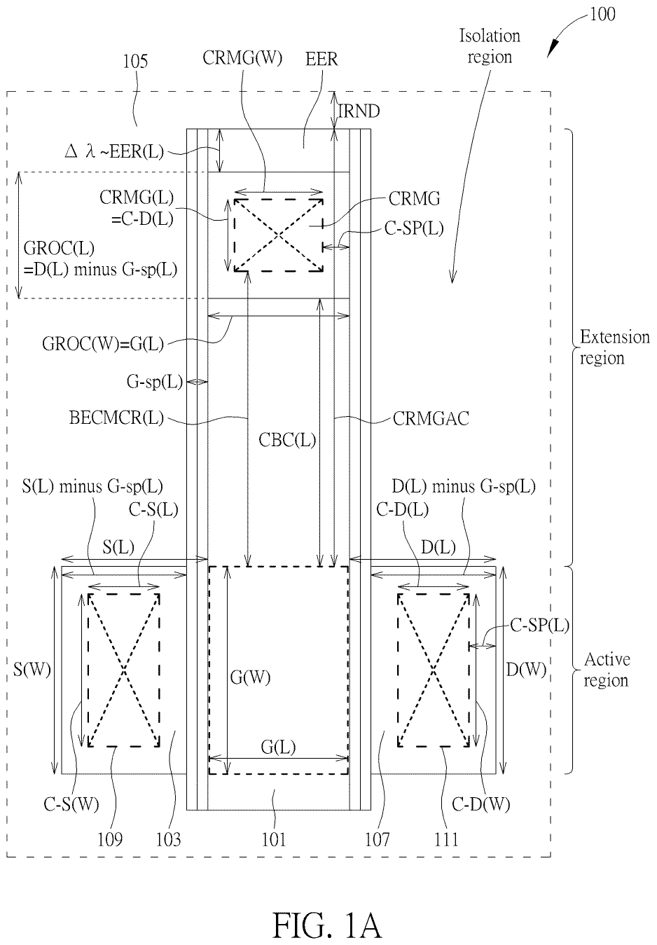

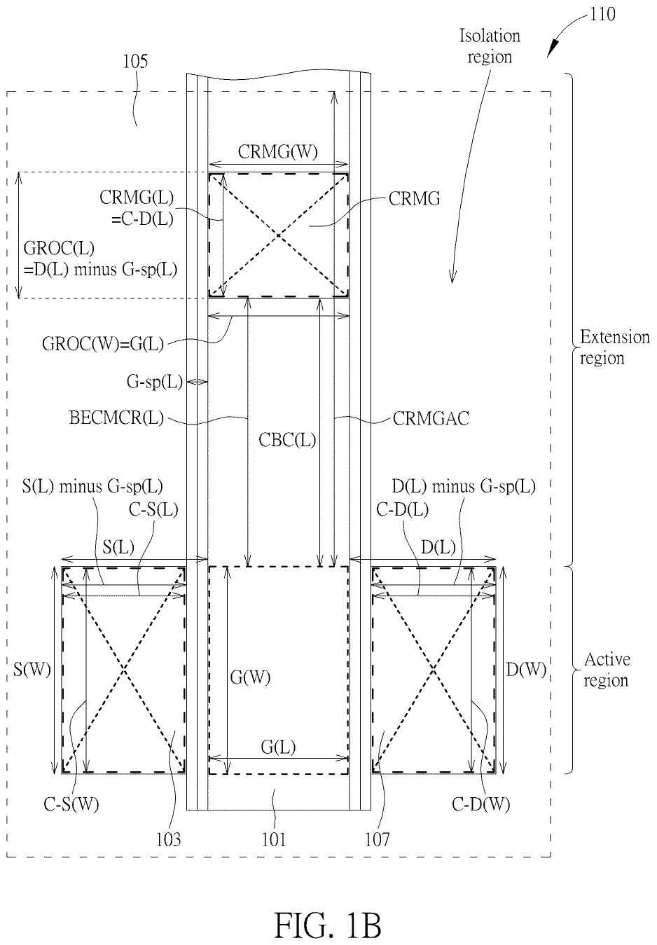

FIG. 1A is a diagram illustrating a top view of a transistor 100 according to an embodiment of the present invention, wherein the new transistor 100 could be a GAA (gate-All-Around) transistor structure and given a name as NuGAAT. The NuGAAT 100 includes a new design to make contact openings on an extension area of a gate structure 101 and on both source region 103 and/or drain region 107 of the NuGAAT 100. The gate structure 101 and channel region of the NuGAAT 100 can use well-developed GAA structure, and the source region 103/the drain region 107 of the NuGAAT 100 can use either n-type dopants for an NMOS transistor or p-type dopants for a PMOS transistor, respectively. In the following description, the present invention utilizes an NMOS transistor as an example with a GAA design, and the final gate formation can use either the gate-first or the gate-last approach by the commonly known prior art design and process without needs to further elaborate descriptions in the following embodiment since these different designs are obvious extensions of the present invention and can be viewed as a straight-forward way of accommodating the suitable ways of forming the NuGAAT 100 accordingly.

As shown in FIG. 1A, a connection region of metal-1 (M1) layer to the gate structure 101 (called as CRMG) is designed with a distance somewhat away from the channel region: in such a design the extension area where the CRMG is located adjacent to the channel region is so called as CRMGAC. Outside and surrounding the CRMG there is a larger framed region within the extension area (named as GROC as an abbreviation of the gate structure 101 over the connection-region). The nitride layer over the extension area within the GROC has been removed for allowing the CRMG to be made for a contact opening on the gate structure 101; the GROC has a length along the longitudinal direction labeled as GROC(L) and a width GROC(W) which is usually about a length G(L) of the gate structure 101. A distance from a bottom edge of the GROC to an edge of the channel region (called as CBC(L)) should be larger than the photolithographic misalignment tolerance (PMT), in order to ensure that the CRMG cannot be directly overlaid on top of the channel region (although a special note here: if any technology allows that the CRMG can be overlaid on top of the gate structure 101 with the device channel beneath it, then the present invention can be applied well without the above stated restrictions; that is, CBC(L) can be as small as zero or in a negative value theoretically). That is, a distance from the bottom edge of the CRMG to the edge of the channel region underneath the gate structure 101 (called as BECMCR(L)) is required to be larger than a sum of the PMT and the spacer width within the GROC. In the CRMG, the CRMG has a vertical distance called as a length of CRMG, i.e. CRMG(L) and a horizontal distance called as the width of CRMG, i.e. CRMG(W). An extra extension area of the gate structure 101, which in FIG. 1A is drawn vertically above the GROC in the longitudinal direction, is reserved for the processing step of defining the gate structure 101 by the gate-level mask (GM) in order to maintain the extra extension area (called as EER with its length as EER(L)) to absorb the PMT during the GM step (e.g. EER(L) could be equal to a Δλ, wherein λ could be the technology node). Because the GROC is needed, an isolation region between any neighboring devices (IRND) must be well designed without violating design rules (which are not the focus of the present invention and can be suitably well designed within the targets). In addition, as shown in FIG. 1A, the gate structure 101 has a length G(L) and a width G(W), the source region 103 on a left-hand side of the gate structure 101 has a length S(L) which is a linear dimension from an edge of the gate structure 101 to an edge of an isolation region 105 and a width S(W), the drain 107 on a right-hand side of the gate structure 101 has a length D(L) which is a linear dimension from the edge of the gate structure 101 to the edge of the isolation region 105 and a width D(W). At a center of the source region 103, a contact opening 109 formed by a self-alignment technology has length and width of an opening labeled as C-S(L) and C-S(W), respectively, and similarly at a center of the drain 107, a contact opening 111 formed by the self-alignment technology has length and width of an opening labeled as C-D(L) and C-D(W), respectively. Moreover, CRMG(L) could be equal to or substantially equal to C-D(L) (or C-S(L)). In addition, FIG. 1B is a diagram illustrating a similar design like the NuGAAT 100 of FIG. 1A except that the gate extension area of the NuGAAT 110 is a long wire to its neighborhood without need of reserving and labeling as EER and IRND, and that C-SP(L) in FIG. 1A which is a length of an oxide spacer could be omitted in FIG. 1B. In addition, FIG. 1A also defines a length G-SP(L). Next, one embodiment of the present invention is described in the following on how semiconductor processing steps can be performed to construct the structure shown in FIG. 1A (or in FIG. 1B).

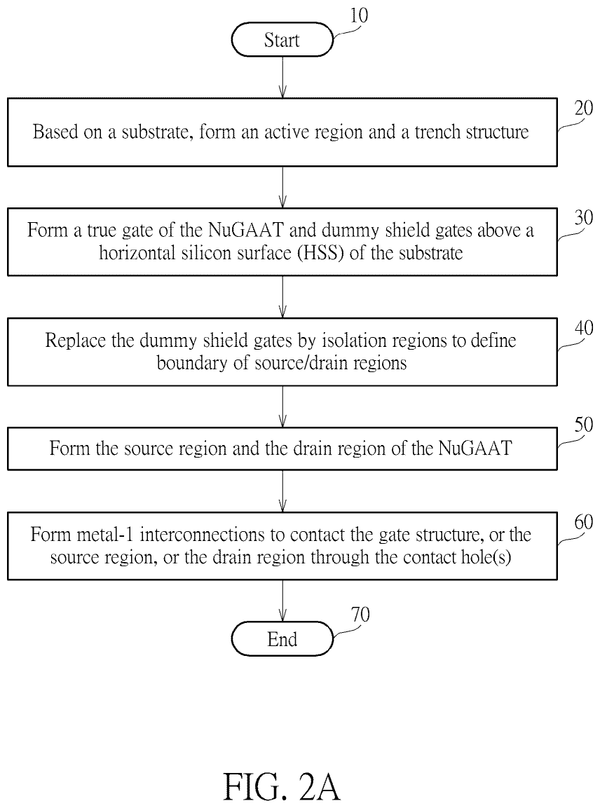

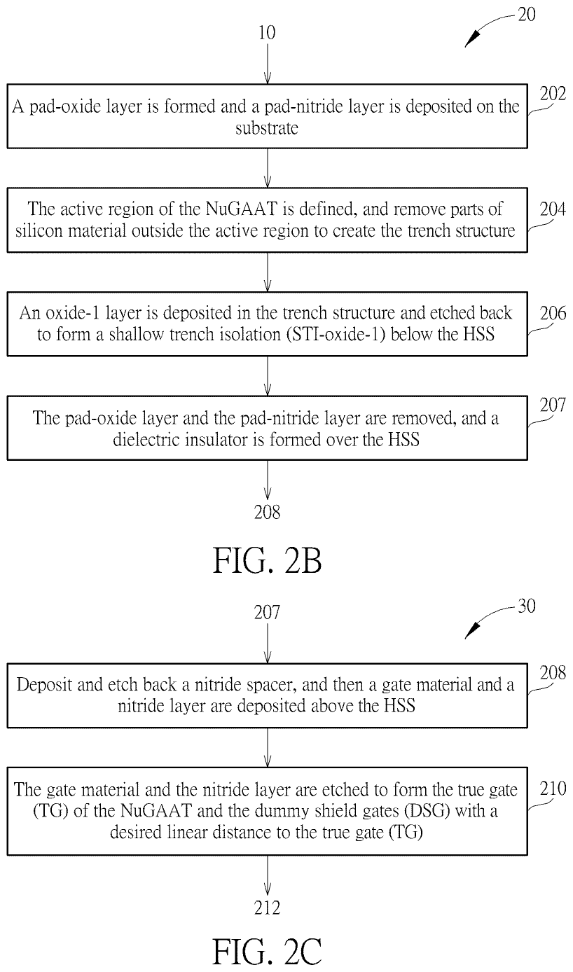

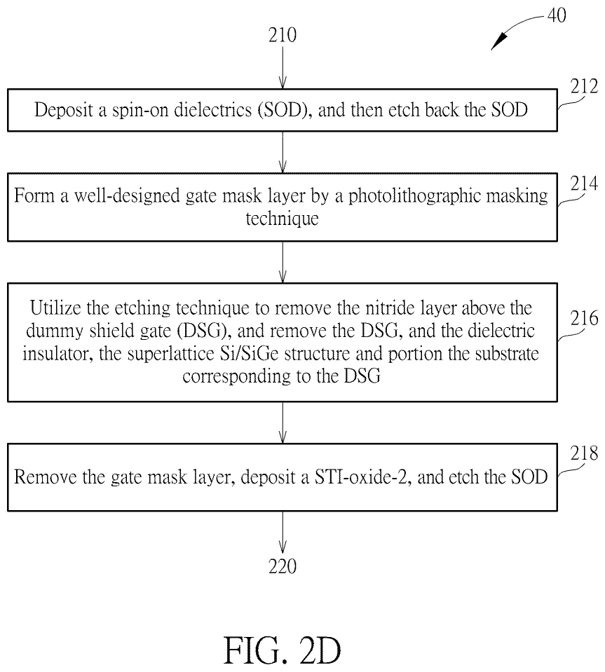

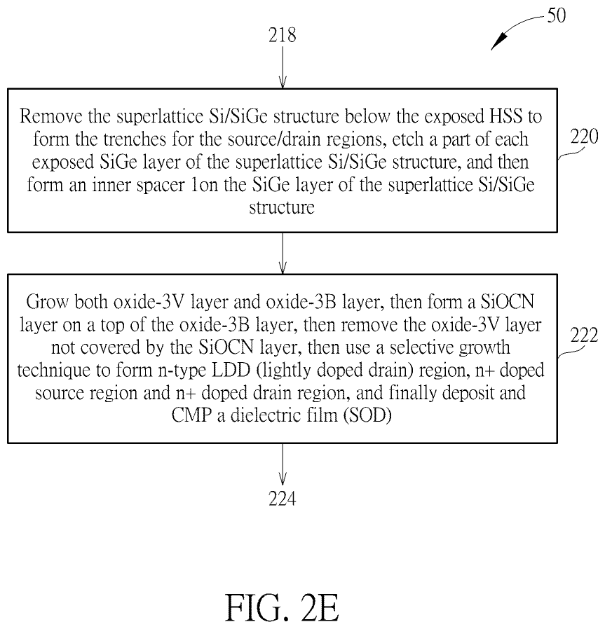

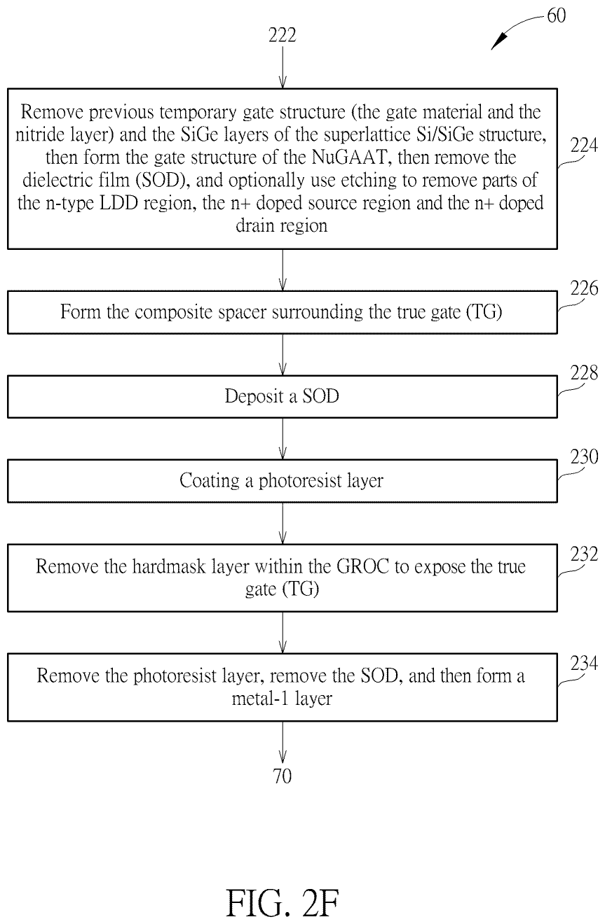

FIG. 2A is a flowchart illustrating a manufacturing process of a NuGAAT (e.g. the NuGAAT 100 shown in FIG. 1A or the NuGAAT 110 shown in FIG. 1B) according to one embodiment of the present invention, wherein the NuGAAT has heat dissipation path to dissipate heat generated from S/D junctions on both a source region and a drain region of the NuGAAT. Detailed steps are as follows:

Step 10: Start.

Step 20: Based on a substrate 102, form an active region and a trench structure.

Step 30: Form a true gate of the NuGAAT and dummy shield gates above a horizontal silicon surface (HSS) of the substrate 102.

Step 40: Replace the dummy shield gates by isolation regions to define boundary of source/drain regions.

Step 50: Form the source region and the drain region of the NuGAAT.

Step 60: Form metal-1 interconnections to contact the gate structure, or the source region, or the drain region through the contact hole (s).

Step 70: End.

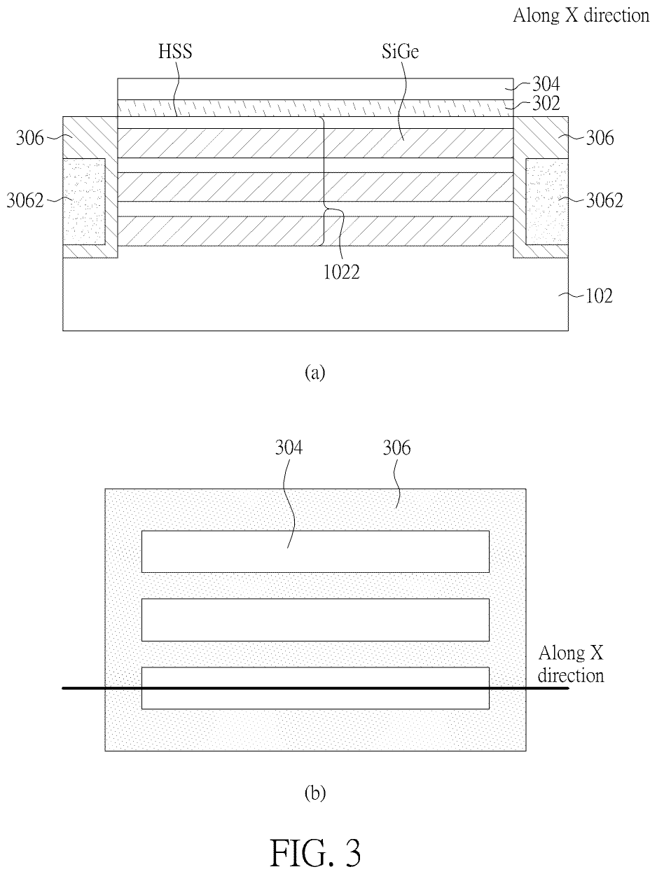

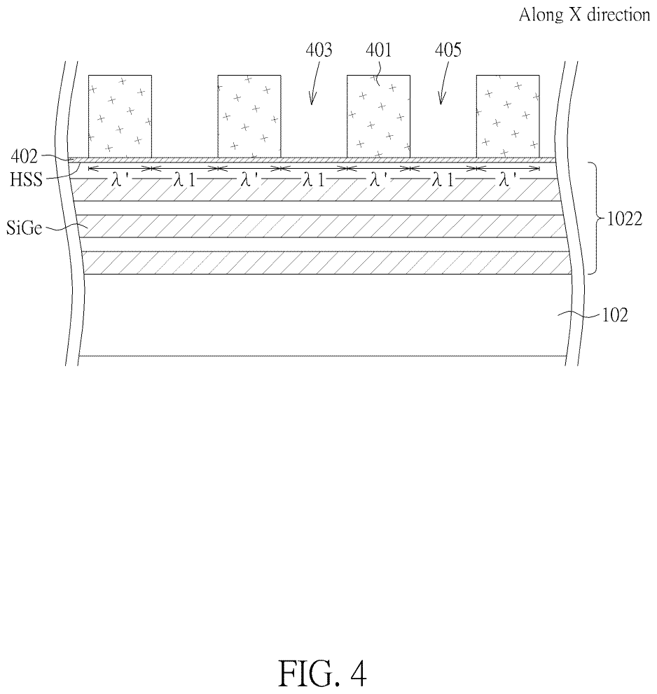

Please refer to FIG. 2B, FIG. 3 and FIG. 4. Step 20 could include:

Step 202: A pad-oxide layer 302 is formed and a pad-nitride layer 304 is deposited on the substrate 102 (FIG. 3).

Step 204: The active region of the NuGAAT is defined, and remove parts of silicon material outside the active region to create the trench structure (FIG. 3).

Step 206: An oxide-1 layer is deposited in the trench structure and etched back to form a shallow trench isolation (STI-oxide-1) 306 below the HSS (FIG. 3).

Step 207: The pad-oxide layer 302 and the pad-nitride layer 304 are removed, and a dielectric insulator 402 is formed over the HSS (FIG. 4).

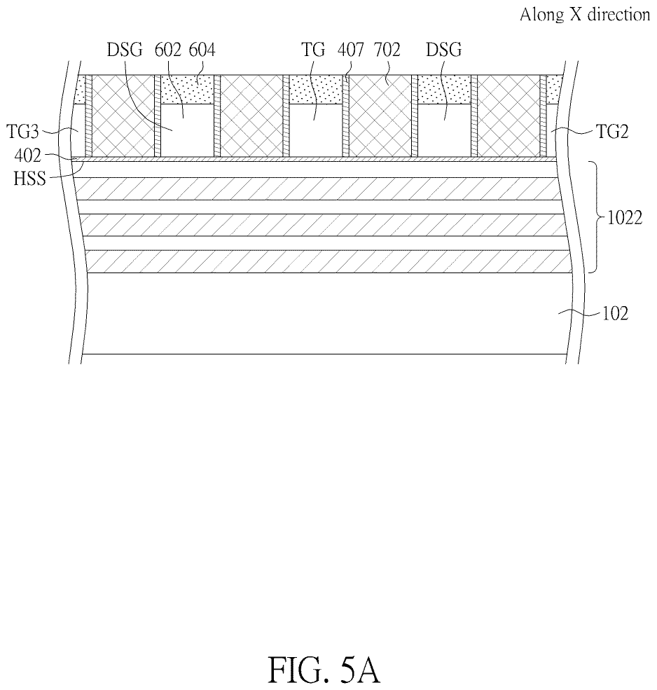

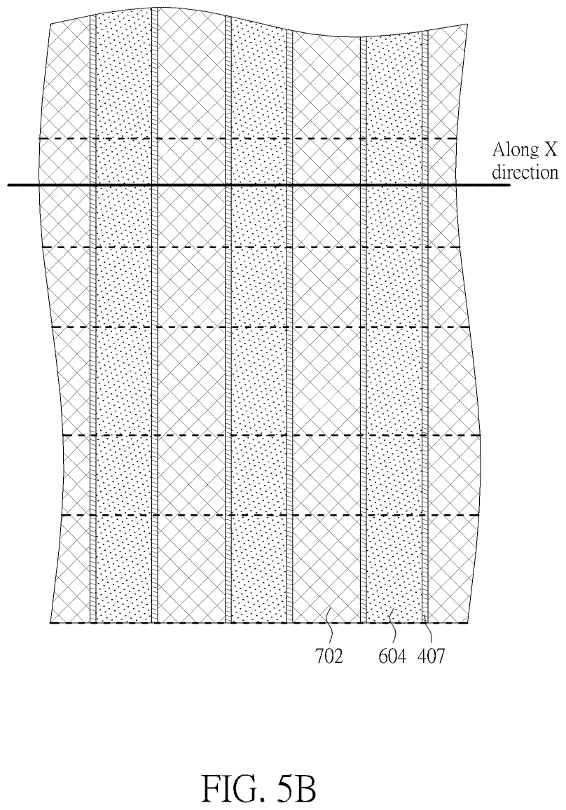

Please refer to FIG. 2C, FIG. 5A and FIG. 5B. Step 30 could include:

Step 208: Deposit and etch back a nitride spacer 407, and then a gate material 602 and a nitride layer 604 are deposited above the HSS (FIG. 5A).

Step 210: The gate material 602 and the nitride layer 604 are etched to form the true gate (TG) of the NuGAAT and the dummy shield gates (DSG) with a desired linear distance to the true gate (TG) (FIG. 5A).

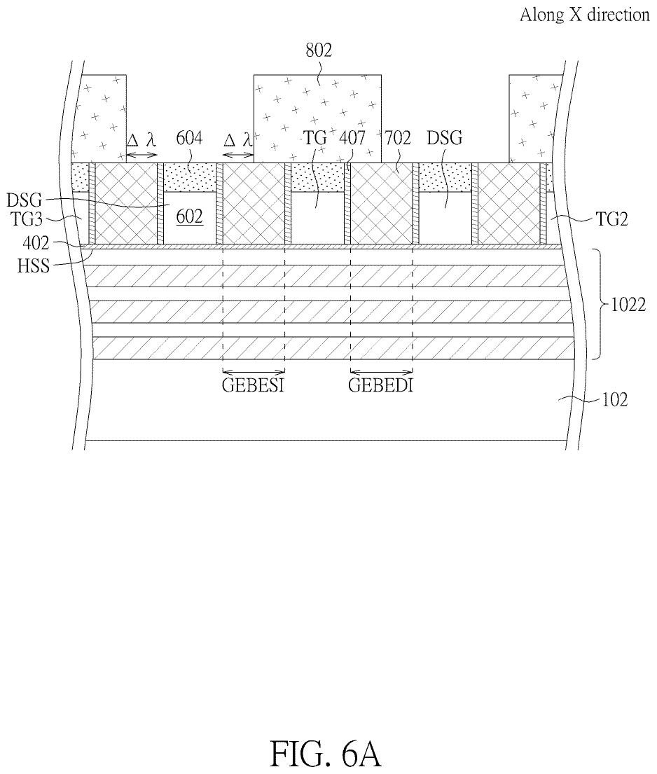

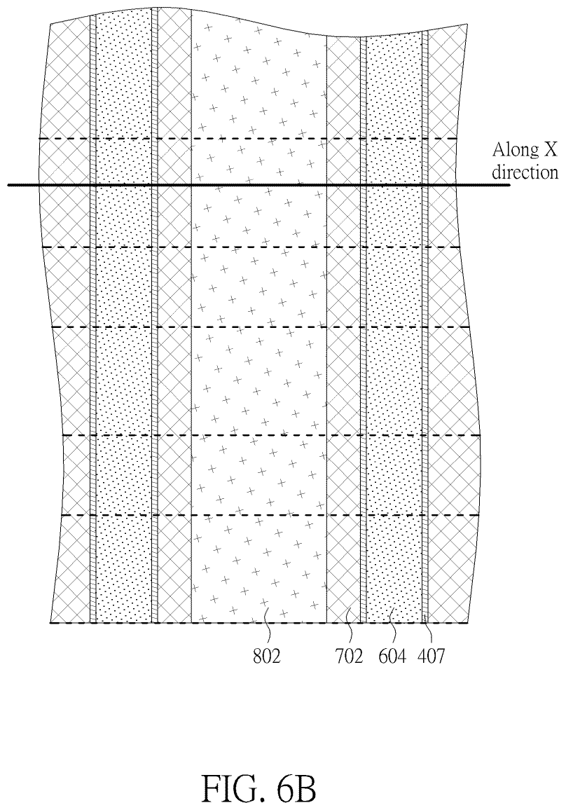

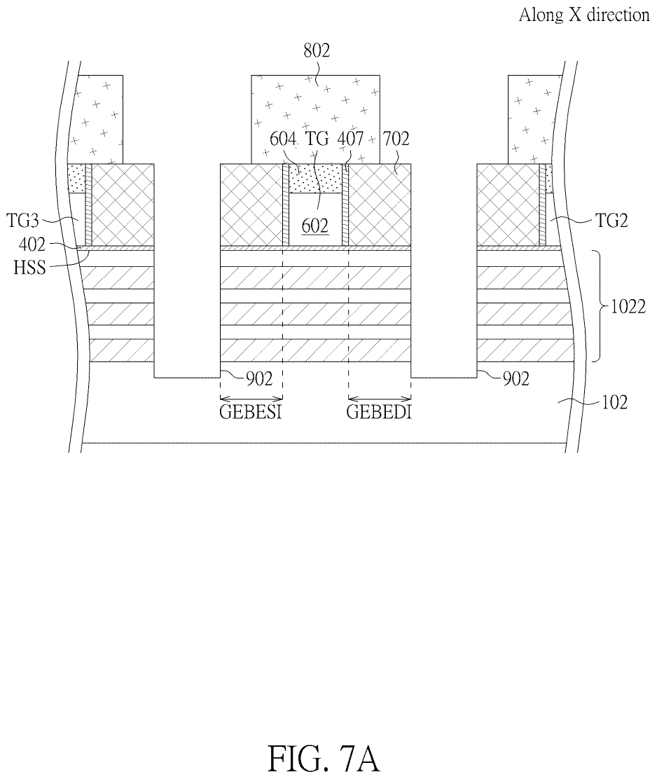

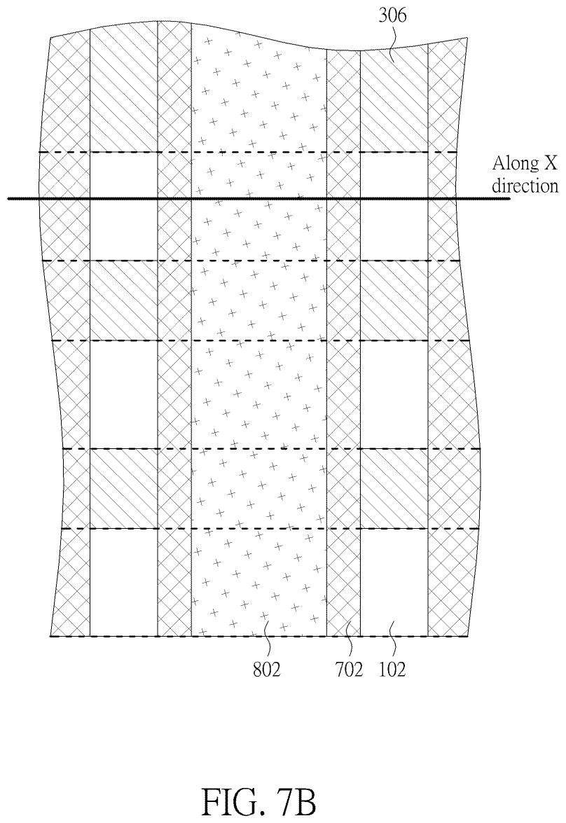

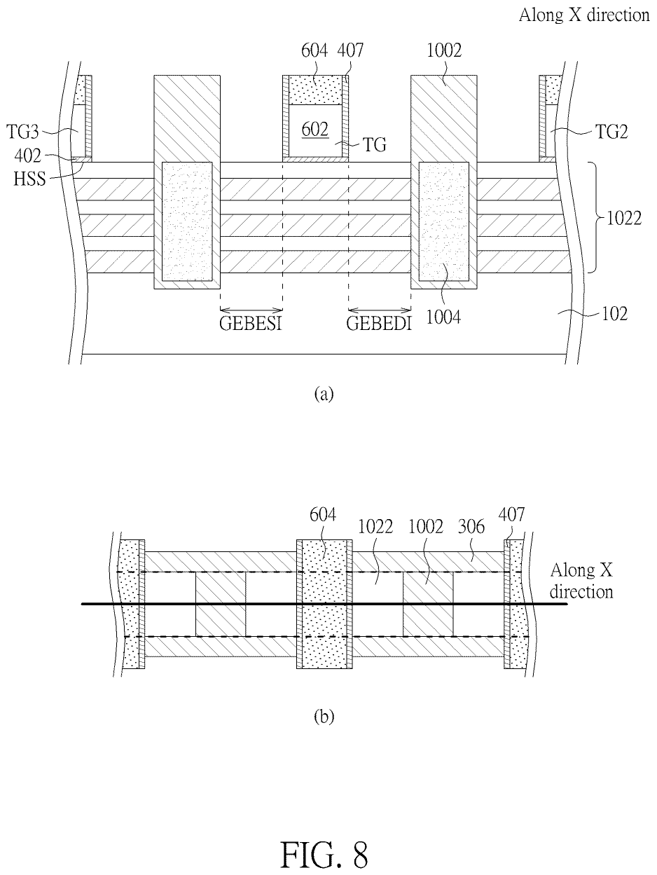

Please refer to FIG. 2D and FIG. 5A, FIG. 5B, FIG. 6A, FIG. 6B, FIG. 7A, FIG. 7B, FIG. 8. Step 40 could include:

Step 212: Deposit a spin-on dielectrics (SOD) 702, and then etch back the SOD 702 (FIG. 5A).

Step 214: Form a well-designed gate mask layer 802 by a photolithographic masking technique (FIG. 6A).

Step 216: Utilize the etching technique to remove the nitride layer 604 above the dummy shield gate (DSG), and remove the DSG, and the dielectric insulator 402, the superlattice Si/SiGe structure 1022 and portion the substrate 102 corresponding to the DSG (FIG. 7A).

Step 218: Remove the gate mask layer 802, deposit a STI-oxide-2 1002, etch the SOD 702 (FIG. 8).

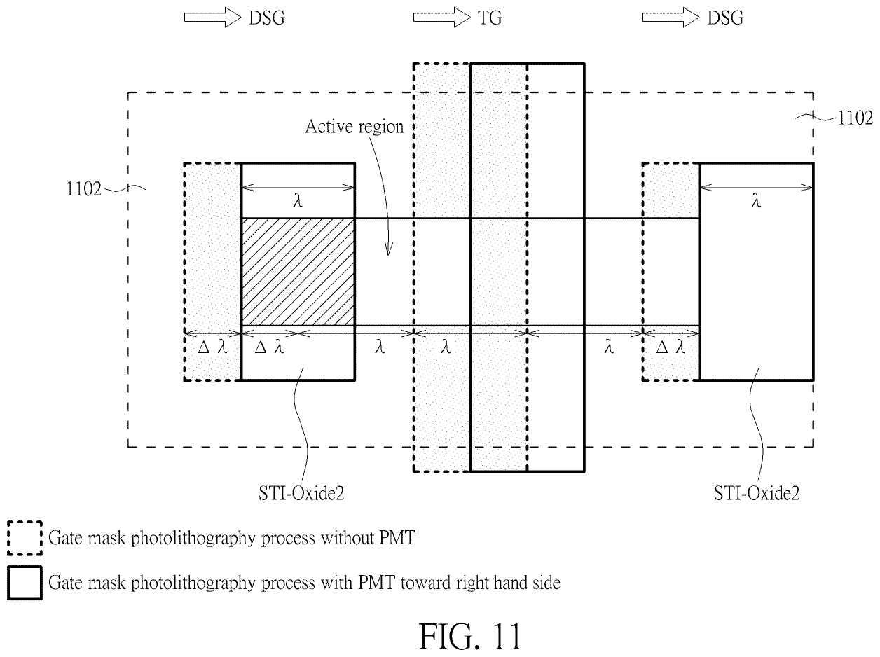

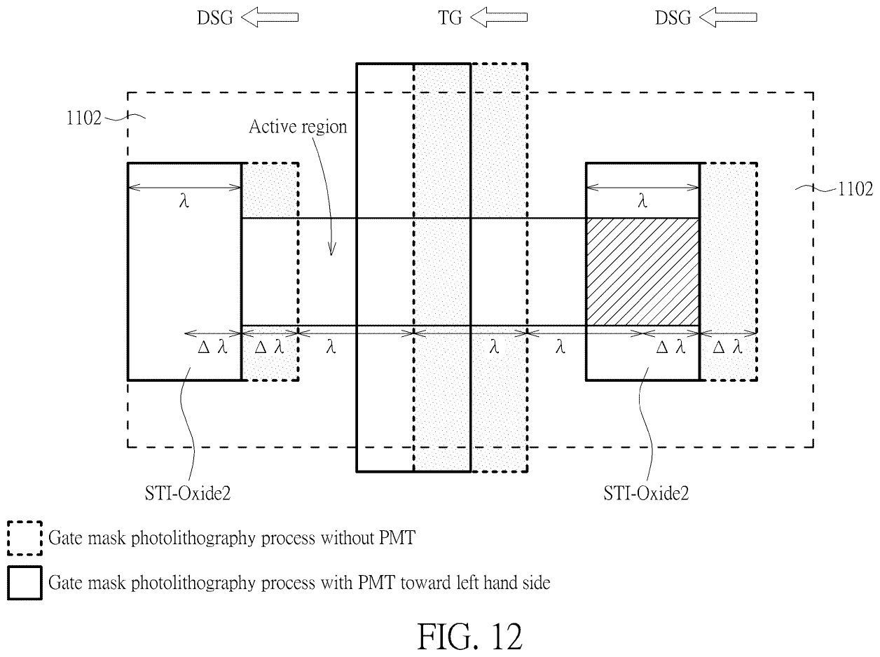

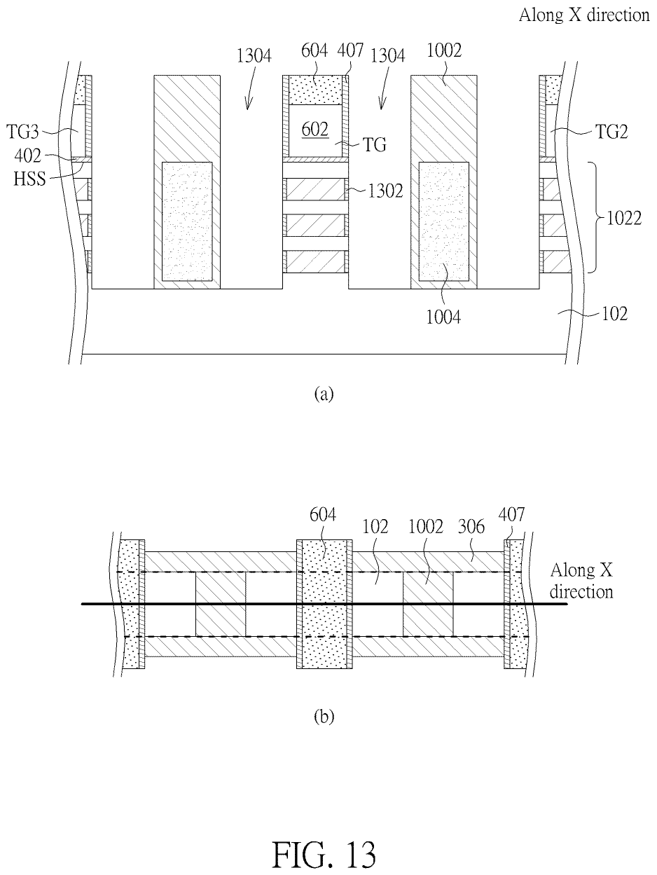

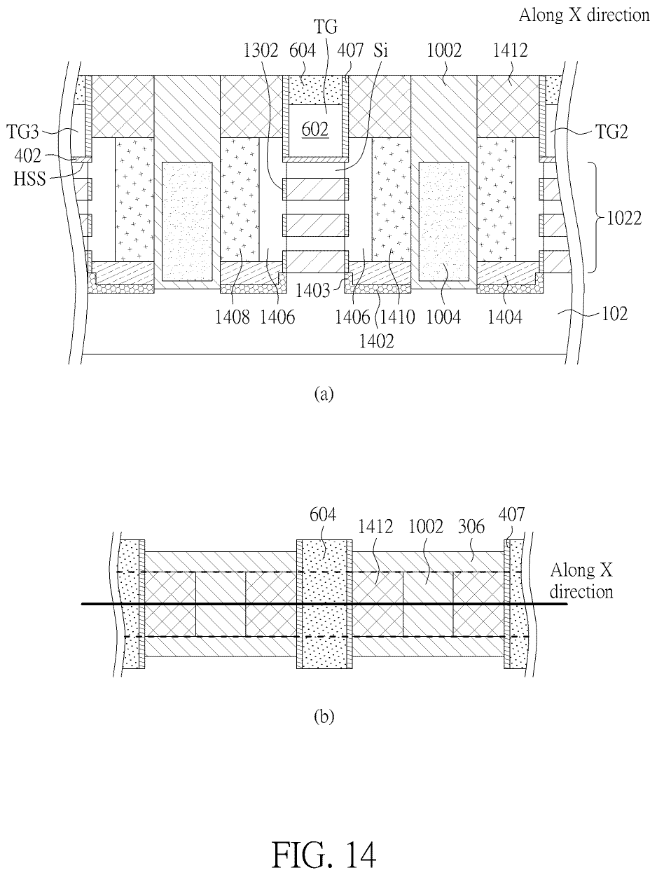

Please refer to FIG. 2E and FIG. 13, FIG. 14. Step 50 could include:

Step 220: Remove the superlattice Si/SiGe structure 1022 below the exposed HSS to form the trenches 1304 for the source/drain regions, etch a part of each exposed SiGe layer of the superlattice Si/SiGe structure 1022, and then form an inner spacer 1302 on the SiGe layer of the superlattice Si/SiGe structure 1022 (FIG. 13).

Step 222: Grow both oxide-3V layer 1403 and oxide-3B layer 1402, then form a SiOCN layer 1404 on a top of the oxide-3B layer 1402, then remove the oxide-3V layer 1403 not covered by the SiOCN layer 1404, then use a selective growth technique (such as selective epitaxy growth) to form n-type LDD (lightly doped drain) region 1406, n+ doped source region 1408 and n+ doped drain region 1410, and finally deposit and CMP a dielectric film (SOD) 1412 (FIG. 14).

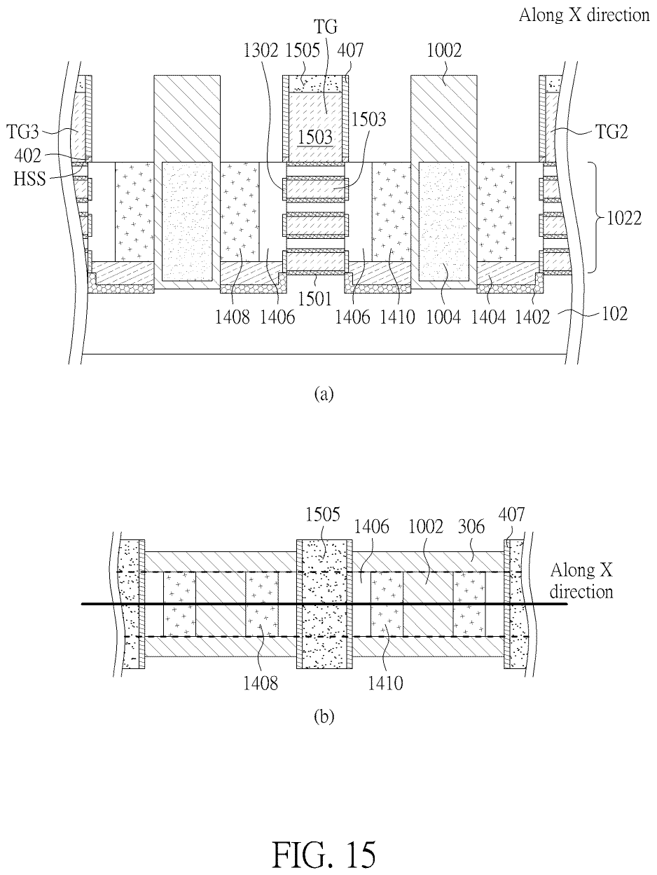

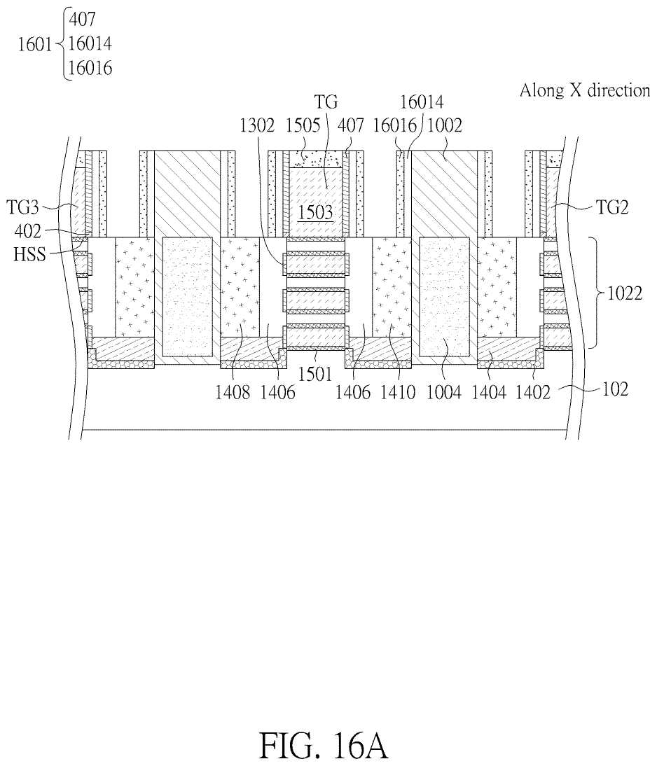

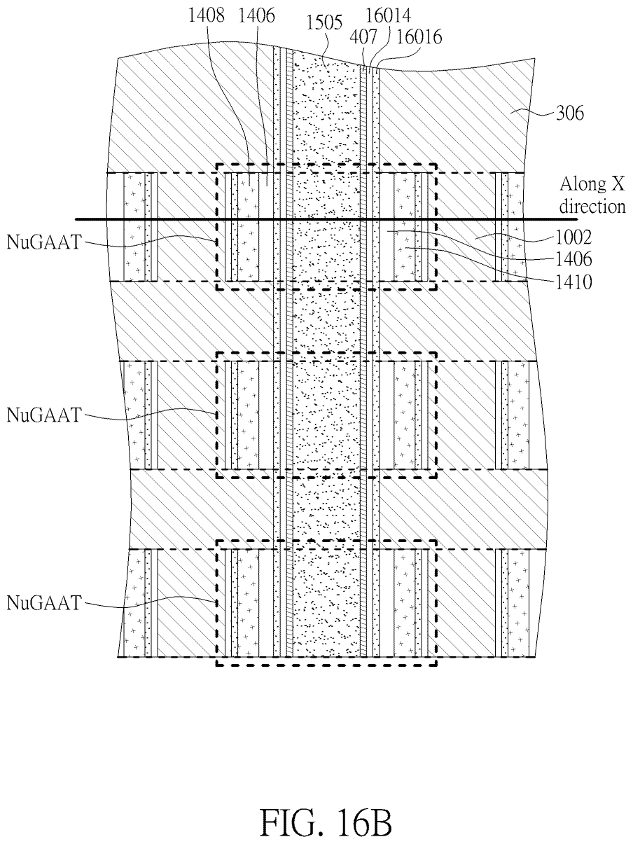

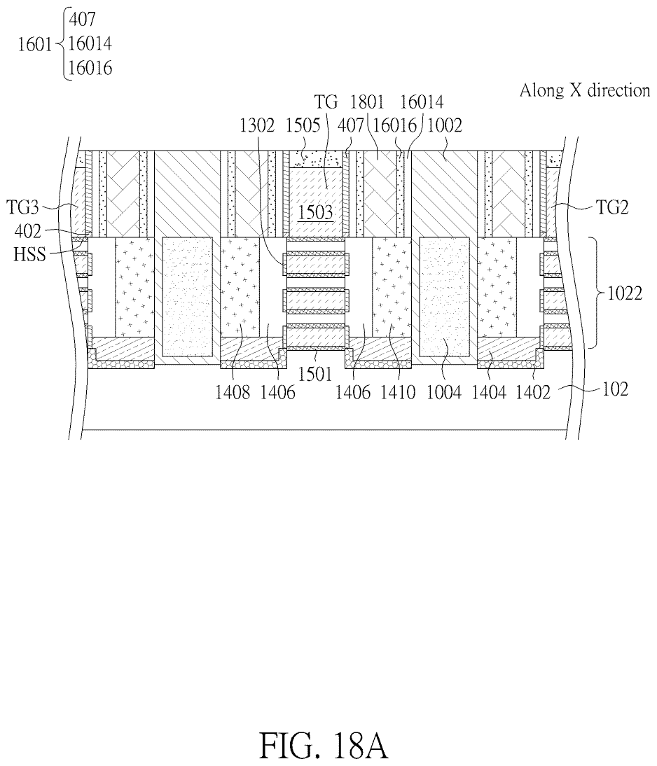

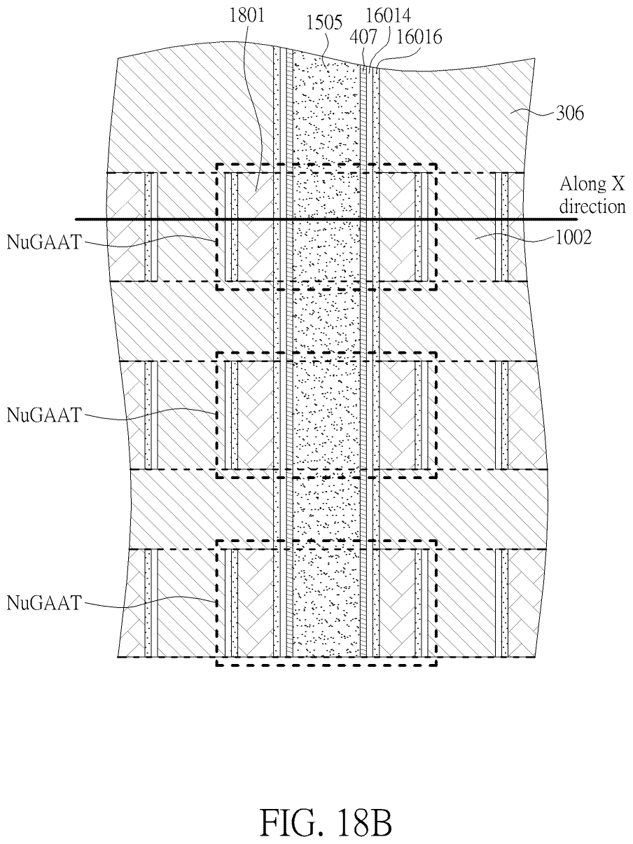

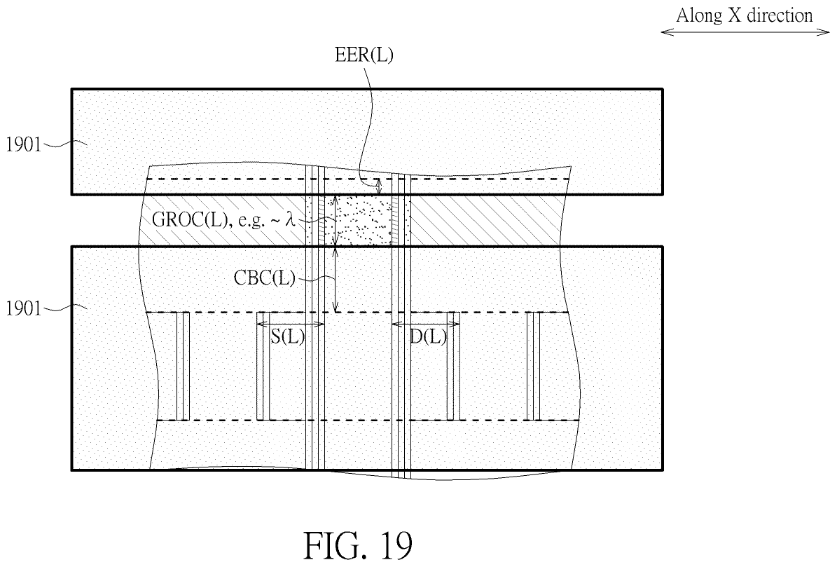

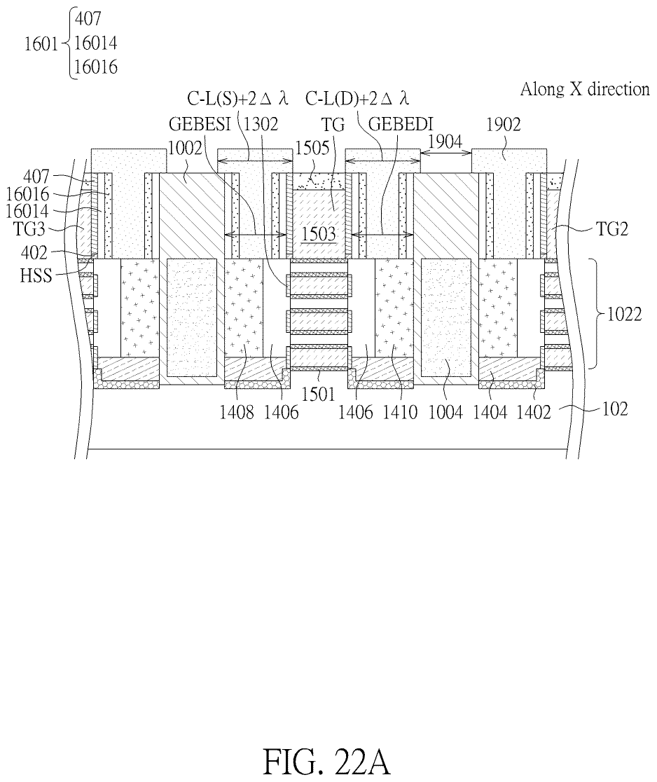

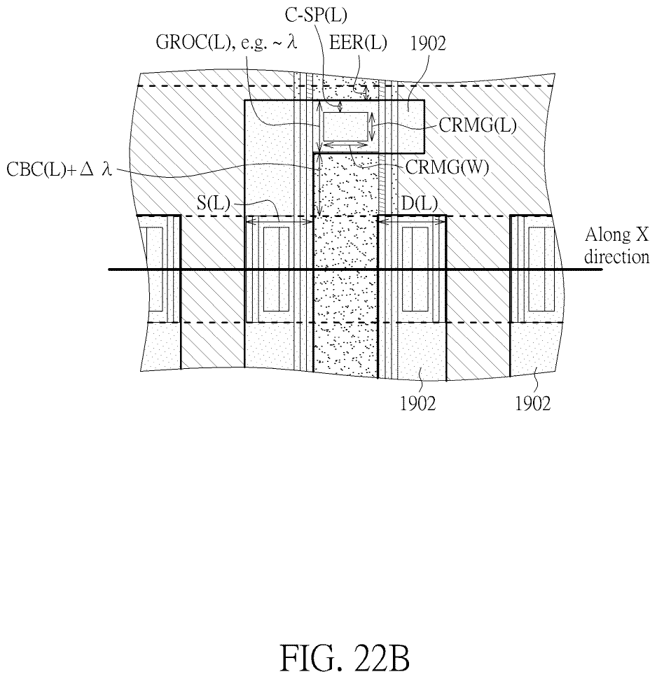

Please refer to FIG. 2F and FIG. 15, FIG. 16A, FIG. 16B, FIG. 18A, FIG. 18B, FIG. 19, FIG. 22A, FIG. 22B. Step 60 could include:

Step 224: Remove previous temporary gate structure (the gate material 602 and the nitride layer 604) and the SiGe layers of the superlattice Si/SiGe structure 1022, then form the gate structure of the NuGAAT, then remove the dielectric film (SOD) 1412, and optionally use etching to remove parts of the n-type LDD region 1406, the n+ doped source region 1408 and the n+ doped drain region 1410 (FIG. 15).

Step 226: Form the composite spacer 1601 surrounding the TG (FIG. 16A).

Step 228: Deposit a SOD 1801 (FIG. 18A).

Step 230: Coating a photoresist layer 1901 (FIG. 19).

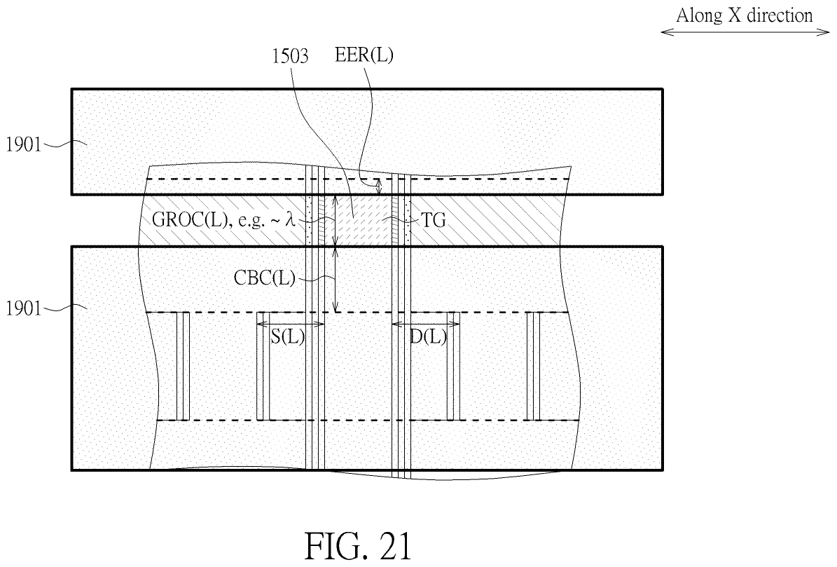

Step 232: Remove the hardmask layer 1505 within the GROC to expose the true gate (TG) (FIG. 21).

Step 234: Remove the photoresist layer 1901, remove the SOD 1801, and then form a metal-1 layer 1902 (FIG. 22A).

The following describes the detailed processes for the manufacture method of the NuGAAT in which the gate structure and source (or drain) region could be connected thought a metal-1 layer.

Use an n-type GAA as an example, the substrate 102 would be a p-type substrate and detailed description of the aforesaid manufacturing process is as follows, wherein the substrate 102 has a superlattice Si/SiGe structure 1022. Start with Step 20, please refer to FIG. 2B and FIG. 3(a). In Step 202, the pad-oxide layer 302 is formed over the HSS of the substrate 102 and then the pad-nitride layer 304 is deposited above the pad-oxide layer 302.

In Step 204, the active region of the NuGAAT can be defined by the photolithographic masking technique, wherein the HSS outside the active region is exposed accordingly. Because the HSS outside the active region pattern is exposed, the parts of the silicon material outside the active region can be removed by the etching technique to create the trench structure.

In Step 206, as shown in FIG. 3(a), form the STI-oxide-1 306 below the HSS to fully fill the trench structures, wherein the STI-oxide-1 306 is named as shallow trench isolation (STI) structure and as shown in FIG. 3(a), and it is noted that the STI structure includes a high thermal conductivity (HTC) material 3062. In addition, FIG. 3(a) is a cross-section view along an X direction shown in FIG. 3(b). In addition, because FIG. 3(b) is a top view, FIG. 3) only shows the pad-nitride layer 304 and the STI-oxide-1 306.

Then, in Step 207, as shown in FIG. 4, the pad-oxide layer 302 and the pad-nitride layer 304 on the active regions are removed, and then the dielectric insulator 402 (with high-K) is formed over the HSS. Then, use a photolithographic mask 401 to define true gate regions 403 and dummy gate regions 405 (which will be replaced by STI region later) of the NuGAAT, wherein the width of the true gate region λ1=T gate (true gate length)+T spacer (gate space width), and λ′ is the spacing in which the source/drain regions will be λ1 and λ′ could be designed based on requirement, for example, λ1 is between 20˜28 nm and λ′ is between 25˜32 nm, for λ=2˜7 nm which is dictated by the photolithographic resolution of the equipment available for the specified processing node or technology node. This describes the normal state-of-the-art design and processing method of accomplishing the geometric relationship between the gate region and the transistor isolation region (STI) with a smaller dimensional size. In this process step, however, there exists an unavoidable non-ideal factor called as Photolithographic Misalignment Tolerance (PMT) during the photolithographic masking step for an alignment of an edge of the gate structure to the edge of the boundary between the source region and the STI-oxide-1 306 (similarly on the other side of the drain region). If this PMT measured in a linear dimension along the X-axis is called Δλ, Δλ should be correlated to the minimal feature size as dictated by the photolithographic resolution of the equipment available for the specified processing node. For example, a 7-nm process node should have its A equal to 7 nm and the Δλ of the PMT could be 3.5 nm or so. Therefore, if the desired actual physical length of the source (or drain) region of the NuGAAT is targeted at λ (e.g. 7 nm), then the designed length of the source (or drain) region under the state-of-the-art process method must be larger than the sum of λ and Δλ (e.g. >10.5 nm).

Therefore, the present invention utilizes the new structural design and its processing implementation methods which can eliminate the above-mentioned negative effect of the PMT. That is, whatever dimension of a distance from the edge of the gate structure to the edge of the boundary between the source region (or the drain region) of the NuGAAT and the STI region, named as GEBESI (or GEBEDI), is desired to be achieved. There is no need to reserve extra dimension for tolerating PMT along the length dimension of the NuGAAT (i.e. along the X direction in FIG. 3(b) and FIG. 4).

In Step 208, in the present invention as shown in FIG. 5A, after the dielectric insulator 402 (with high-K) is formed over the HSS, first, deposit and etch back the nitride spacer 407 within the true gate regions 403 and the dummy gate regions 405, then the gate material 602 and the nitride layer 604 are deposited, and then remove the photolithographic mask 401. Then in Step 210, the gate material 602 and the nitride layer 604 are etched to form the gate structure (wherein the gate material 602 could be the gate conductive layer of the NuGAAT). As shown in FIG. 5A, when a true gate (TG) of the NuGAAT is defined by the photolithographic masking technique, dummy shield gates (DSG) are also defined in parallel to the TG with a desired, so targeted linear distance (e.g. λ, such as 7 nm in the 7-nm process node) exists between the DSG and the TG without reserving any extra dimension (i.e. Δλ) for the PMT. Both the DSG and the TG designed on the same mask could be formed simultaneously on a top of the dielectric insulator 402 which covers the active regions. In addition, as shown in FIG. 5A, TG2, TG3 correspond to other NuGAATs. In addition, FIG. 5B is a top view of FIG. 5A, wherein as shown in FIG. 5B, the nitride layer 604 covers on tops of both TG and DSG.

The following steps describe how to replace the dummy shield gates by isolation regions which are raised above the HSS. In Step 212, as shown in FIG. 5A, the SOD 702 is deposited and the chemical mechanical polishing (CMP) technique is utilized to etch back the SOD 702, and make a top of the SOD 702 as tall as a top of the nitride layer 604.

In Step 214, as shown in FIG. 6A, the gate mask layer 802 (well-designed) is deposited, and then the gate mask layer 802 is etched by the photolithographic masking technique to accomplish a target of covering the TG, TG2, TG3 but exposing the DSG with a safe PMT margin Δλ at a middle of such lengths of GEBESI and GEBEDI, respectively. In addition, FIG. 6B is a top view of FIG. 6A.

In Step 216, as shown in FIG. 7A, the etching technique is utilized to etch away the DSG and the nitride layer 604 corresponding to the DSG, and further to etch away part of the dielectric insulator 402 corresponding to the DSG so as to reach the HSS, and then the etching technique is utilized to remove the superlattice Si/SiGe structure 1022 (corresponding to the DSG) below the HSS (such as to a depth as a depth of a bottom of the STI-oxide-1 306 mentioned in FIG. 3(a)). Therefore, as shown in FIG. 7A, the PMT is avoided in creation of precisely controlled lengths of GEBESI and GEBEDI, respectively. Since the lengths of GEBESI and GEBEDI are well defined by the TG and the DSG on the same mask, both the length S(L) of the source region and the length D(L) of the drain region shown in FIG. 1A are thus well defined and made. That is, the dimensions of the length S(L) and the length D(L) can be accurately controlled even for achieving an optimally minimized dimension as small as the minimum feature size A. Because the length S(L) and the length D(L) can be can be equal to A, the length S(L) and the length D(L) are substantially equal to the length of the TG (i.e. the gate structure). In addition, FIG. 7B is the top view of FIG. 7A.

In Step 218, as shown in FIG. 8(a), remove the gate mask layer 802 and then form the STI-oxide-2 layer 1002 to fill the trenches where the previous DSG were located and other vacancies on the HSS, wherein the STI-oxide-2 layer 1002 further includes a high thermal conductivity (HTC) material 1004 and a height of the high thermal conductivity (HTC) material 1004 is adjustable (i.e. the height of the high thermal conductivity (HTC) material 1004 can be higher or lower than the HSS, or leveled up to the HSS or a top of TG). Then, use a CMP (Chemical Mechanical Polishing) technique to make the STI-oxide-2 layer 1002 have a planar surface, wherein the planar surface of the STI-oxide-2 layer 1002 could be aligned with the top of the nitride layer 604 on the TG. Therefore, as shown in FIG. 8(a), it is very clear that the STI-oxide-2 layer 1002 is raised up above the HSS.

As shown in FIG. 8(a), then remove the SOD 702 and the dielectric insulator 402 under the SOD 702 to expose the HSS in both the source and drain regions which are surrounded by the STI-oxide-2 layer 1002 and the nitride spacer 407 surrounding the TG. Then any existing ways of forming the source region and the drain region can be used to complete the NuGAAT, wherein the source region and the drain region would be formed respectively according to the precisely controlled GEBESI and the GEBEDI. In addition, FIG. 8(b) is the top view of FIG. 8(a).

Since a shape of an isolation region of a transistor and a position of the isolation region from the transistor to neighboring transistors could be quite varied (even from the above-mentioned embodiment), another structure invention on how to design an adaptive DSG by extending principles of the above-mentioned embodiment is described in the following.

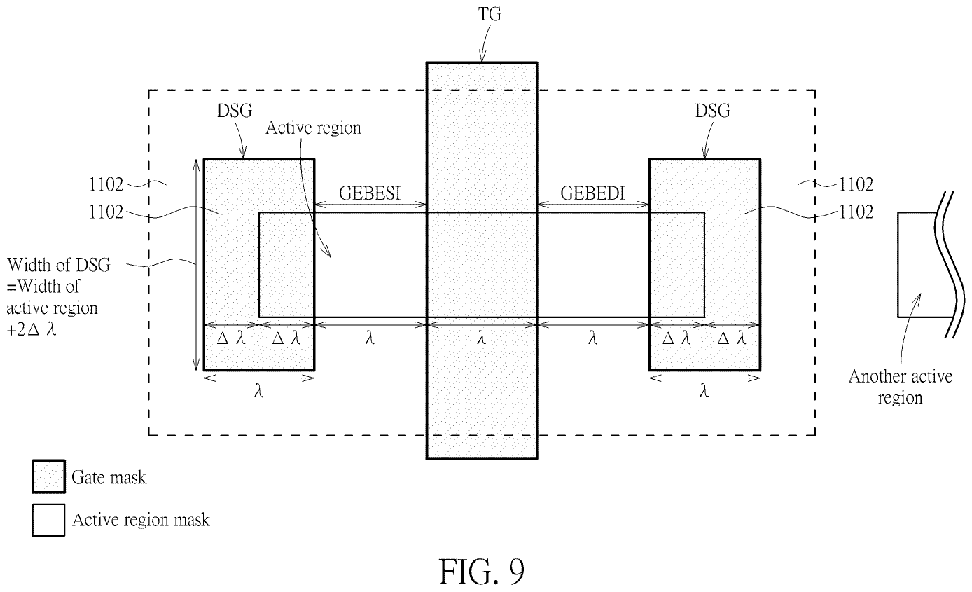

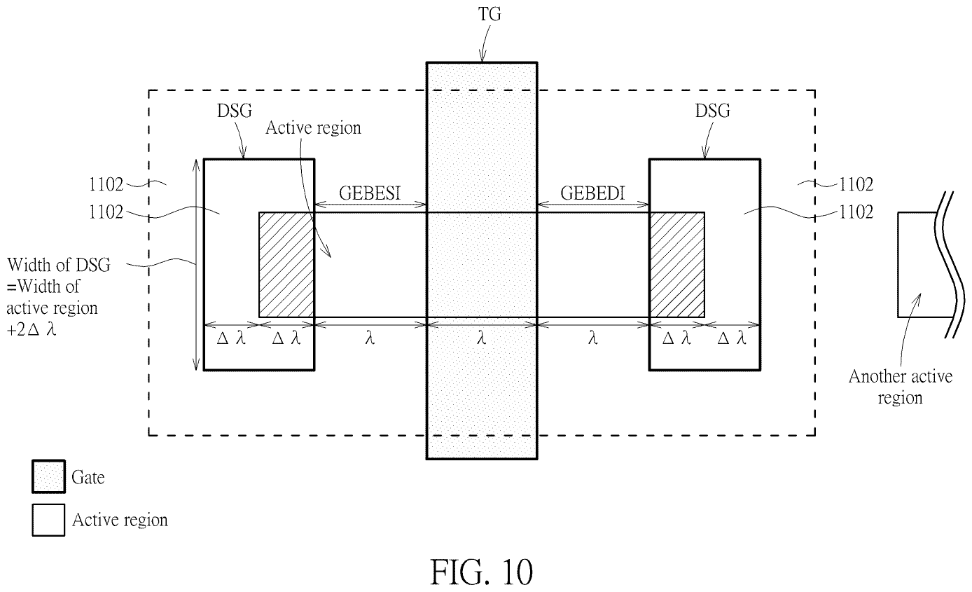

FIG. 9 shows a different geometric condition where active regions of neighboring transistors are laid out differently from FIG. 5A. For example, as shown in FIG. 5A, adjacent active regions of the neighboring transistors are made to be connected before the true gate (TG), true gate 2 (TG2), true gate 3 (TG3), the dummy shield gate (DSG) and the SOD 702 are deposited, and then the DSG is used for dividing the connected active regions into individual precisely-targeted distance by a length of the DSG. But, as shown in FIG. 9, it is assumed that an active region on a source (or a drain) of a transistor is totally isolated (by isolation region 1102) from any other active regions before and after a TG of the transistor is defined. Therefore, what is proposed here is how to design both the active region on the source side and an adaptive DSG as described below (similarly for the drain region). For example, if a final length of the GEBESI is targeted at λ (or any other targeted length L(S)), and then a length of an active region mask (“AA mask”) corresponding to the GEBESI side should be designed to be equal to a sum of λ and Δλ (or a sum of the length L(S) and Δλ). Then on a gate mask, the DSG could have a shape as shown in FIG. 9, that is, a rectangular shape for the DSG has a length equal to λ and a width equal to a sum of a width of the active region and 2Δλ (each side shares 0.5Δλ, respectively). The designed distance between the TG and the DSG on the source side is still just the length of GEBESI, e.g. λ.

The result derived from mask levels of the active region and the gate of FIG. 7A onto wafer level is portrayed in FIG. 10. As shown in FIG. 10, when the TG is defined by the photolithographic masking technique, the DSG is made in parallel to the TG with a targeted distance (e.g. λ, such as 7 nm in the 7-nm process node) between the DSG and the TG. With a nominal processing result (that is, no significant misalignment is induced by the photolithographic processing), the DSG covers partially the active region (corresponding to the source) by a distance LA and both the TG and the DSG are printed on the top of the dielectric insulator 402 which covers the active regions. There are the nitride layer 604 on the top of both the TG and the DSG.

If the PMT causes a shift (e.g. Δλ) of both the TG and the DSG toward the right-hand side of the active region (FIG. 11), the subsequent processing to remove the DSG for achieving isolation region (i.e. STI-oxide-2 layer) exactly at the location of this previously existing the DSG location as described by the aforementioned processing steps should result in the STI-oxide-2 layer with a length A and the STI-oxide-2 layer turns out a physical geometry of the source region which has its GEBESI length equal to λ (since the distance between the TG and the DSG is designed to be equal to λ). On the other hand, if the PMT causes a shift (e.g. Δλ) of both the TG and the DSG toward the left-hand side of the active region (FIG. 12), the subsequent processing steps of removing the DSG and forming the STI-oxide-2 layer will result in the STI-oxide-2 layer with a length λ and the source region has still its GEBESI length equal to λ.

When the PMT causes undesirable shifts along the width direction (that is, up or down direction) of the active region, the design of such an adaptive dummy shield gate having the width of the sum of the width of the active region and 2Δλ should not affect the geometric dimensions of the active region. The novel design of using the adaptive dummy shield gate can always result in the STI-oxide-2 layer with the length λ and the length of the GEBESI fit to the designed target (e.g. as narrow as λ). The present invention can surely be applied to all varied shapes of isolation regions, source regions and drain regions with their individual targeted lengths, respectively.

After disclosing how both GEBESI and GEBEDI can be optimally designed and fabricated to a precisely controlled small dimension (which can be as small as λ), another new invention is how to create a smaller dimension (called as length C-S(L) and length C-D(L), respectively, as defined in FIG. 1A of the contact openings than the lengths of GEBESI and GEBEDI, respectively. Two designs and the process formations are described in the following.

By continuing the implementation following FIG. 8(a), and utilizing the TG to explain in the following, in Step 220, as shown in FIG. 13(a), first utilize an anisotropic etching technique to remove the superlattice Si/SiGe structure 1022 below the exposed HSS to form the trenches 1304 for the source/drain regions, wherein the trenches 1304 have a depth close to the depth of a bottom of the STI-oxide-2 layer 1002. Then, in the trenches 1304, etch a part of each exposed SiGe layer (under the TG) of the superlattice Si/SiGe structure 1022 to control the growth position and size of a subsequently formed inner spacer 1302. Afterward, deposit a thinner layer and controllably etch the thinner layer to form the inner spacer 1302 on the SiGe layer (under the TG) of the superlattice Si/SiGe structure 1022. In addition, FIG. 13(b) is the top view of FIG. 13(a).

In Step 222, as shown in FIG. 14(a), use a thermal oxide process to grow both oxide-3V layer 1403 covering the vertical sidewalls of the revealed Si part (under the TG) of the superlattice Si/SiGe structure 1022 and oxide-3B layer 1402 covering bottoms of the trenches 1304. Then, use a SiOCN chemical vapor deposition (CVD) and etch back to form a SiOCN layer 1404 on the top of the oxide-3B layer 1402. Then carry out an etching process to remove the oxide-3V layer 1403 not covered by the SiOCN layer 1404. Afterward, use the selective growth technique (such as selective epitaxy growth) to form n-type LDD (lightly doped drain) region 1406, n+ doped source region 1408 and n+ doped drain region 1410. To be mentioned, no ion-implantations are required for forming all channel, drain and source regions.

Finally, deposit the dielectric film (SOD) 1412 above the n-type LDD region 1406, the n+ doped source region 1408 and n+ doped drain region 1410 and CMP the dielectric film (SOD) 1412 equal to a height as tall as to the top of the nitride layer 604 (over TG). In addition, FIG. 14(b) is the top view of FIG. 14(a).

In Step 224, as shown in FIG. 15(a), then carry out an etching process to remove previous temporary gate structure (the gate material 602 and the nitride layer 604) and the SiGe layers of the superlattice Si/SiGe structure 1022, such that silicon nanowires are formed. Thereafter, the high-K dielectric layer 1501, the gate conductive layer 1503 and the hardmask layer 1505 are formed by a damascene gate process to form the gate structure of the NuGAAT, wherein the gate conductive layer 1503 can be a metal gate with suitable work function or polysilicon. In one embodiment, the bottom of the extension region of the gate structure (that is, the gate structure outside the active region, see FIG. 1A) is lower than the bottom of the source/drain regions. Finally, the dielectric film (SOD) 1412 is removed and then etch optionally to remove parts of the n-type LDD region 1406, the n+ doped source region 1408 and the n+ doped drain region 1410 to reach the HSS. In addition, FIG. 15(b) is the top view of FIG. 15(a).

In Step 226, as shown in FIG. 16A, form the composite spacer 1601 surrounding the TG, wherein the composite spacer 1601 includes the nitride spacer 407, a high thermal conductive thin film 16014 and an oxide-3 layer 16016, and positional relationship between the nitride spacer 407, the high thermal conductive thin film 16014 and the oxide-3 layer 16016 can be referred in FIG. 16A, so further description thereof is omitted. In addition, FIG. 16B is the top view of FIG. 16A and shows multiple NuGAATs.

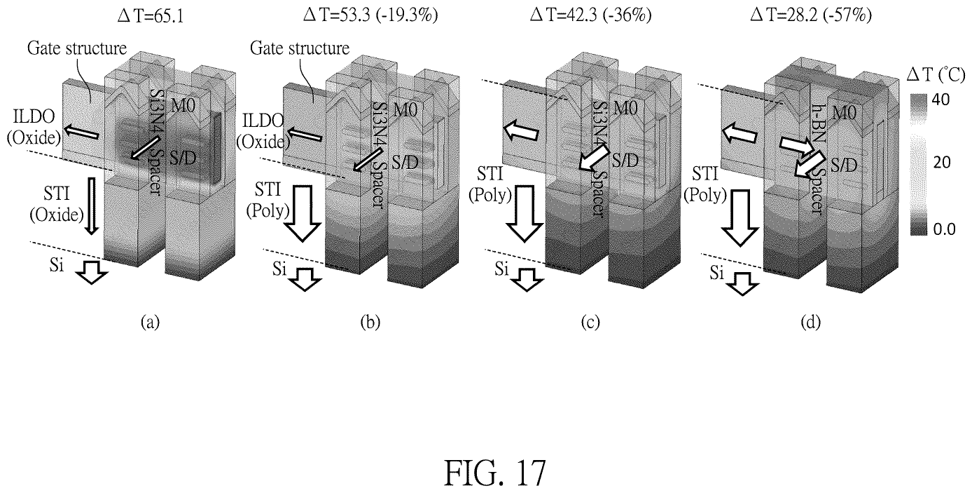

It is noted that the hardmask layer 1505 (or gate cap dielectric layer) over the gate conductive layer 1503 could also comprise the high thermal conductivity (HTC) material thin film, wherein the exemplary HTC materials are summarized in TABLE I and the thermal dissipation effects by 3D technology computer-aided design (TCAD) are compared in FIG. 17.

TABLE I
the hardmask

| layer 1505 | Conventional | | | The present invention | | | |
|---|---|---|---|---|---|---|---|
| (14~20 nm) | Si₃N₄ | SiO₂ | SiOCN | SiC | polysilicon | h-BN | AlN |
| Thermal | 2 | 1.4 | 0.1~0.95 | 20 | ~35 | | ~40 |
| conductivity | | | | | | | |
| (W/m-k) | | | | | | | |
| Dielectric | 7.1 | 3.9 | 2.2~5 | 6.5 | 29.5 | 3.29~3.76 | 8.5 |
| constant | | | | | | | |

| | | |
|---|---|---|
| Advantage | Low dielectric | High thermal |
| | constant | conductivity near hot spot |

FIG. 17(a) shows the thermal dissipation effect by 3D TCAD in a conventional transistor and FIG. 17(b), FIG. 17(c), FIG. 17(d) show the thermal dissipation effects by 3D TCAD in the NuGAAT, wherein the NuGAAT (in FIG. 17(b)) has composite STI region (the top of the HTC material therein is not above the HSS), the NuGAAT (in FIG. 17(c)) has a composite STI region (the top of the HTC material therein is above the HSS), the NuGAAT (in FIG. 17(d)) has the composite STI region (the top of the HTC material therein is above the HSS) and the composite spacer 1601, and the composite STI region includes the STI-oxide-2 layer 1002 and the HTC material. The composite spacer 1601 will be connected to or thermally coupled to the composite STI region, and the composite STI region surrounds the active region, especially three sides of the source/drain regions. Therefore, as shown in FIG. 17(b), FIG. 17(c), FIG. 17(d), the NuGAAT with the composite STI region and the composite spacer 1601 can reduce the junction temperature thereof. In addition, in FIG. 17(d), in TCAD model, the composite spacer 1601 could include 1˜2 nm of SiO₂ enclosing the 4˜5 nm HTC material (e.g., h-BN). In addition, as shown in FIG. 17, ΔT result is the difference between junction maximum temperature and the average chip temperature at equilibrium, S/D represents the source/drain regions of the transistor and ILD is an abbreviation of inter-layer dielectric.

Here, the composite STI region could be divided into two portions, one is the STI portion and the other is the ILD portion, the top of the STI portion is leveled up to HSS and surrounds at least three sides of the source/drain region, and the ILD portion is on the STI portion (or in another example, the top of the STI portion is close to the bottom of the source/drain regions, and the ILD portion is on the STI portion and surrounds at least three sides of the source/drain region). In FIG. 17(b), the HTC material is just located in the STI portion. In FIG. 17(c) and FIG. 17(d), the HTC material is located in both the STI portion and the ILD portion.

In Step 228, as shown in FIG. 18A, the SOD 1801 is deposited to fill the vacancies on the wafer, and then use CMP to make the surface flat including the hardmask layer 1505 over the gate conductive layer 1503, the composite spacer 1601 surrounding the gate conductive layer 1503, and the SOD 1801 is above both the drain and source regions. In addition, FIG. 18B is a top view of the FIG. 18A and shows multiple NuGAATs in the horizontal direction.

The following steps are to proceed forming contact openings on the gate structure of the NuGAAT, specifically on the extension region of CRMGAC (defined in FIG. 1A). In Step 230, as shown in FIG. 19, use a well-designed mask (CG mask, i.e. connection to gate mask) to define the photoresist layer 1901 which results in some stripe patterns (along the X-direction shown in FIG. 19) with a separate space of GROC(L) which cover areas of the CBC(L) and the EER(L), respectively, but expose an area of the GROC with a designed distance CRMGG(L). If under a nominal photolithographic processing method without any significant PMT, then the result is shown as a top view in FIG. 19. For example, herewith assumes the most aggressive design rules with the GROC(L)=λ; it is very important to notice that the GROC(L) should be designed to have approximately equal length like the length S(L) of the source region and the length D(L) of the drain region, respectively, so that by the later processing results the lengths of contact openings on the gate structure, the source region, and the drain region can be achieved to have almost the same sizes for the metal-1 layer with a well-designed enough thickness to completely fill into the contact openings.

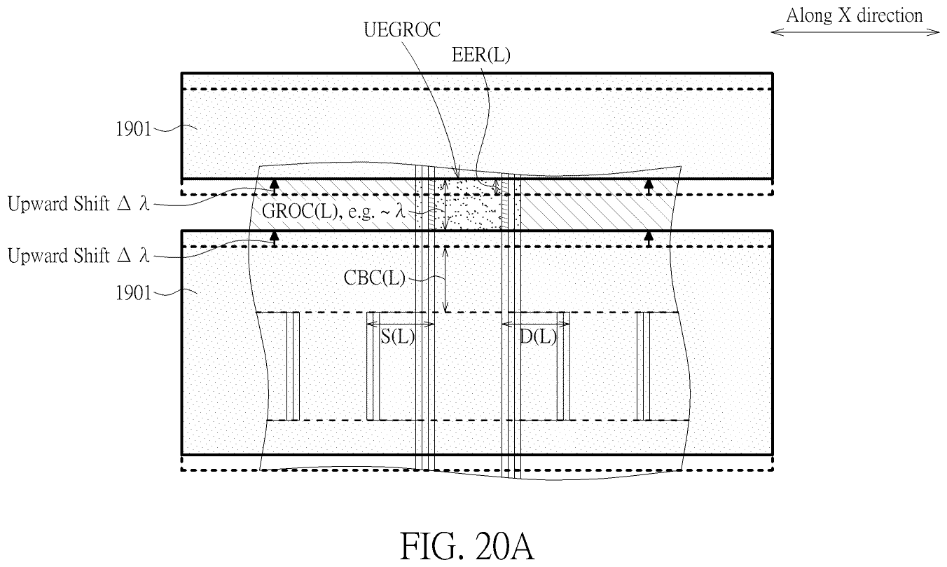

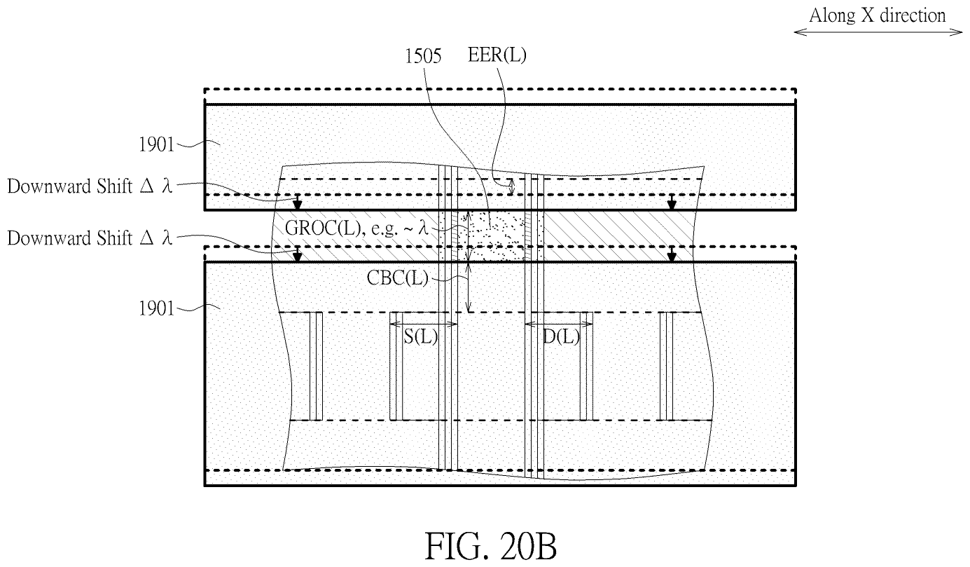

FIG. 20A, FIG. 20B show two possible scenarios, respectively: (a) if the CG photolithographic masking step results in a shift of the PR mask upward by a LA due to PMT, then an upper edge of GROC (called as UEGROC) could exactly cover up the EER; (b) if the CG masking effect results in a shift of the PR mask downward by a LA due to PMT, then the GROC is closer to the channel region but does not disturb the channel region since there is a reserved distance CBC(L). The important point of the present invention is to keep the GROC (L) just like the designed target without being affected by any PMT and almost equal to the length S(L) of the source region and the length D(L) of the drain region, respectively.

In Step 232, as shown in FIG. 21, use the etching technique to remove the hardmask layer 1505 within the GROC to expose the gate conductive layer 1503 (TG).

In conventional contact-hole mask used in the semiconductor manufacture process, there are lots of contact mask patterns each of which is rectangle-like or square-like shape, and those contact mask patterns will be reproduced based on photolithographic process to define the two dimension lengths of the contact hole openings.

As the shrink of the minimum feature size, extreme ultraviolet lithography (EUV), complicated etching technologies, exhausted contact opening and extreme tight design rules are required to avoid the misalignment issues. Nevertheless, in the present invention, the mask pattern only defines one dimension length of the contact hole opening (e.g., the vertical length in FIG. 19), and has nothing to do with another dimension length of the contact hole opening. The another dimension length of the contact hole opening is defined or controlled by the self-alignment processes described previously. Thus, the misalignment issues could be better controlled.

In Step 234, as shown in FIG. 22A, remove the photoresist layer 1901, and then remove the SOD 1801 so that the concave regions on top of the source region (the n-type LDD region 1406 and the n+ doped source region 1408), the drain region (the n-type LDD region 1406 and the n+ doped drain region 1410), and the GROC are exposed. Therefore, a natural built-up contact opening is formed on the source region, the drain region, and the GROC, respectively. As shown in FIG. 22A, when the SOD 1801 is removed to form the concave regions and expose both the source region and the drain region, the concave regions exposing the source region and the drain region are surrounded by walls of the STI-oxide-2 layer 1002 and a wall of the gate conductive layer 1503 (TG) which already includes the composite spacer 1601. As shown in FIG. 22A, then form the metal-1 layer 1902 (landing pad) which has the well-designed thickness to fill in the holes of all the aforementioned contact openings and result in a smooth planar surface following the topography of the wafer surface. Then, use the photolithographic masking technique to create all the connections among those contact openings respectively to achieve the necessary metal-1 interconnection networks (shown in FIG. 22A and FIG. 22B). Therefore, the metal-1 layer 1902 completes the tasks of achieving both the contact-filling and the plug-connection to both the gate structure and the source/the drain regions as well as a direct interconnection function of connecting all transistors. There is no need to use an expensive and very rigidly controlled conventional contact opening mask and carrying on the subsequent very difficult process of drilling the contact openings, especially which should be the most difficult challenges in further scaling down the horizontal geometries of billions of transistors. In addition, it eliminates making both a metal plug into the contact openings and the CMP technique to achieve a metal stud with complex integrated processing step (e.g. as definitely required for some leading-edge technology of creating a Metal-Zero structure). Furthermore, in the present invention, all the contact openings on the gate structure and the source/the drain regions are all made within those regions and their structures have smaller geometries without being made on top of the surrounding oxide isolation regions (thus not only achieving narrow contact opening but also allowing the STI regions without be affected by the contact opening especially very narrow separations for STI are required when the technology needs to be further scaled). In addition, FIG. 22A shows a cross section of a structure of the NuGAAT, especially focusing on contact openings on extension area of the gate structure, the source region, and the drain region, respectively. In addition, FIG. 22B shows top view of the structure of the NuGAAT in FIG. 22A.

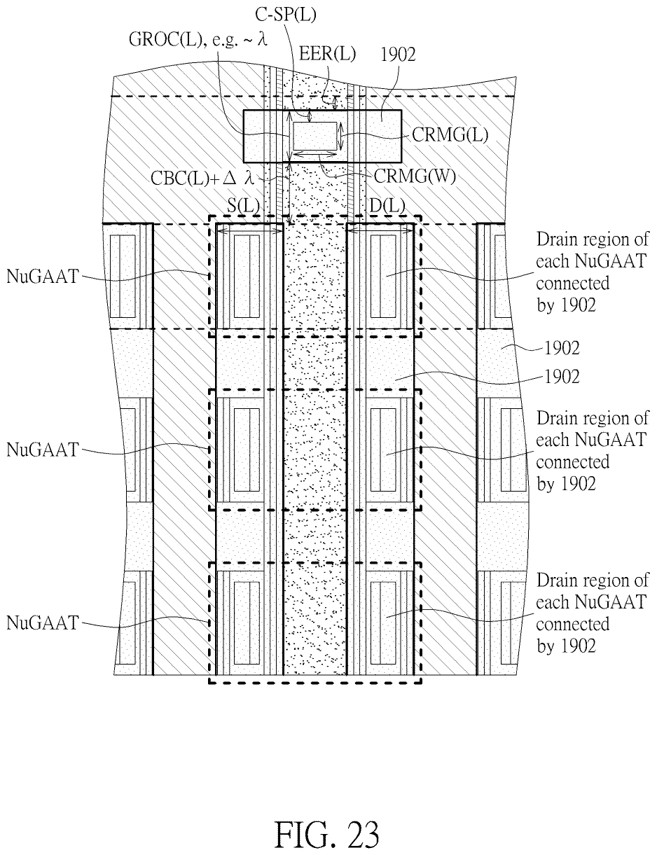

FIG. 23 is a top view of another embodiment with separate multiple NuGAATs extending in horizontal direction, in which all drain regions in those NuGAATs are connected together through the metal-1 layer 1902, and all source regions in those NuGAATs are connected together through the metal-1 layer 1902 as well.

In the following several embodiments of completing different NuGAAT structures especially on their source/drain structures (after the processing step described in FIG. 18A) will be illustrated to cover more varieties of this NuGAAT.

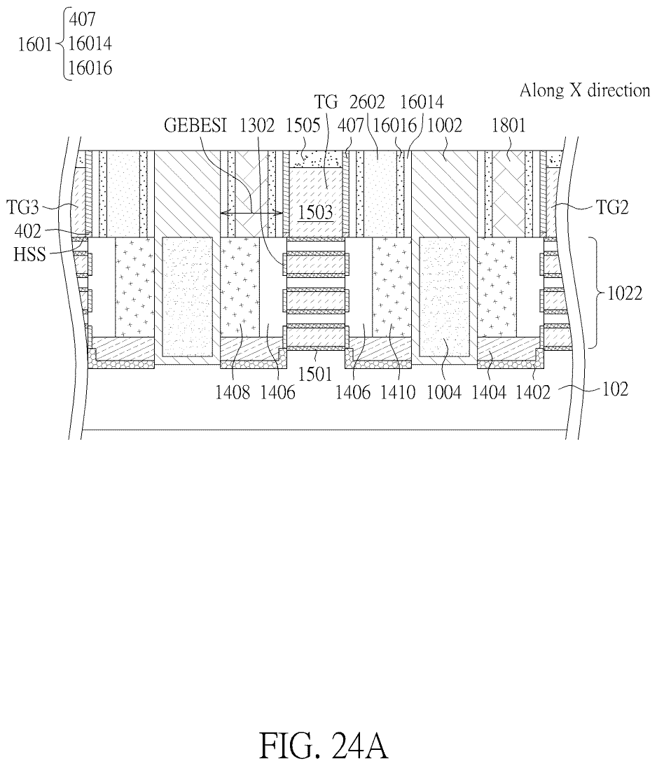

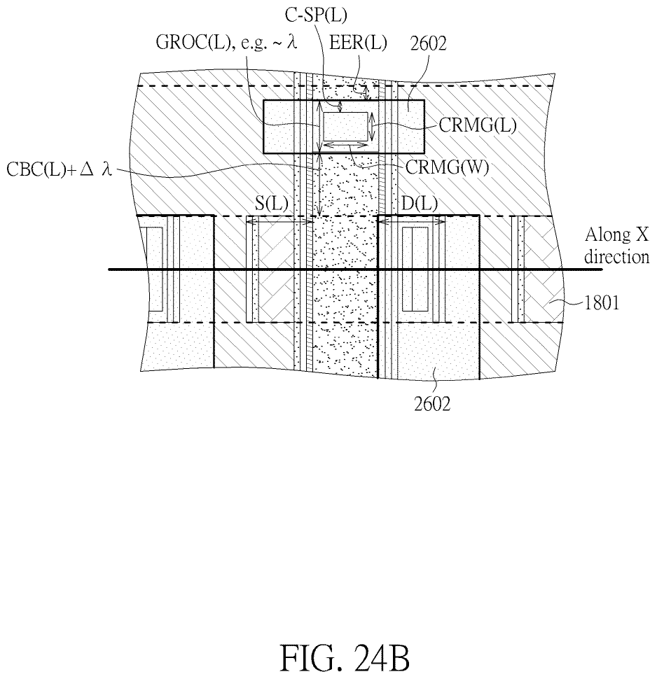

FIG. 24A, FIG. 24B show both cross-section and top view of the NuGAAT at the stage of forming contact openings on the source region (the n-type LDD region 1406 and the n+ doped source region 1408) and the drain region (the n-type LDD region 1406 and the n+ doped drain region 1410), respectively. As shown in FIG. 24A, because in another embodiment of the present invention, the contact openings on the source region are not needed, only the SOD 1801 above the drain region is removed, resulting in space on top of the source region being protected by the SOD 1801. As shown in FIG. 24A, deposit a metal-1 layer 2602 to fully fill the contact openings on top of the gate structure and the drain region, respectively. Then, use the photolithographic masking technique to create all the connections among those contact openings respectively to achieve the necessary metal-1 interconnection networks and the following etching step can create the defined metal-1 networks. In addition, FIG. 24B is the top view of the NuGAAT shown in FIG. 24A.

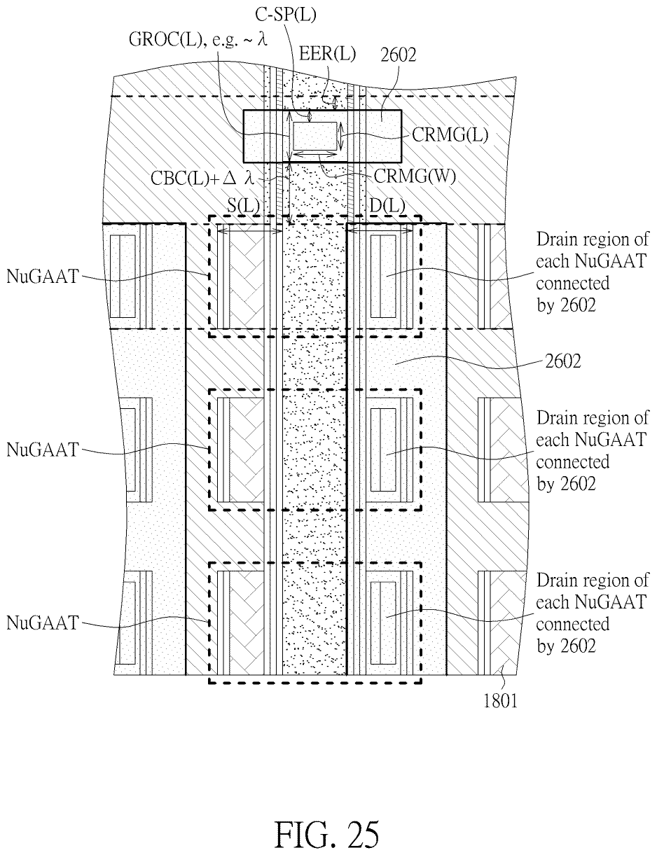

FIG. 25 shows a top view of another NuGAAT with a layout design using separate multiple NuGAATs for drain regions. Since the drain regions can be precisely defined without photolithographic misalignment tolerance (PMT) and the contact openings are well formed separately inside the drain regions by self-alignment with precise geometries, the subsequent metal-1 layer formation in the defined patterns can connect these drain regions directly; otherwise in state-of-the art design on multiple NuGAATs there is a need to use an extra drain region to connect these NuGAATs, which is called a Dog-bone drain structure. This Dog-bone drain structure cause extra areas and more parasitic capacitances for the conventional MOSFET and requires an extra rule to limit the distance between the gate structure and an edge of the Dog-bone, thus causing much larger drain area than the new way of connecting multiple NuGAATs directly by the metal-1 layer 2602. The present invention in achieving the very compact layout design of using the metal-1 layer 2602 to connect the multiple drain regions of the NuGAATs is believed to be the first time of showing a compact layout for the 3D-shaped NuGAAT structures and clearly stands out its advantages, which is very important to help scaling the NuGAAT which uses multiple very narrow drain regions especially in NuGAAT structures.

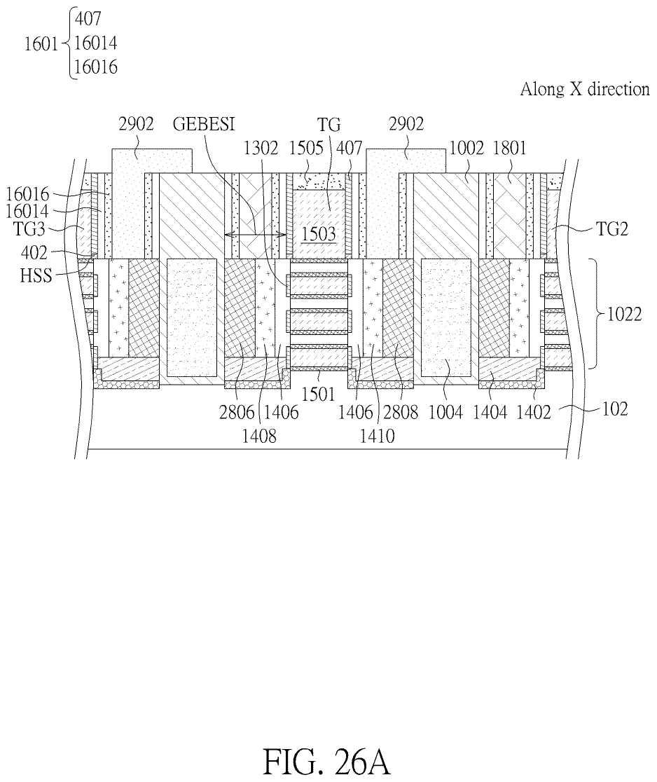

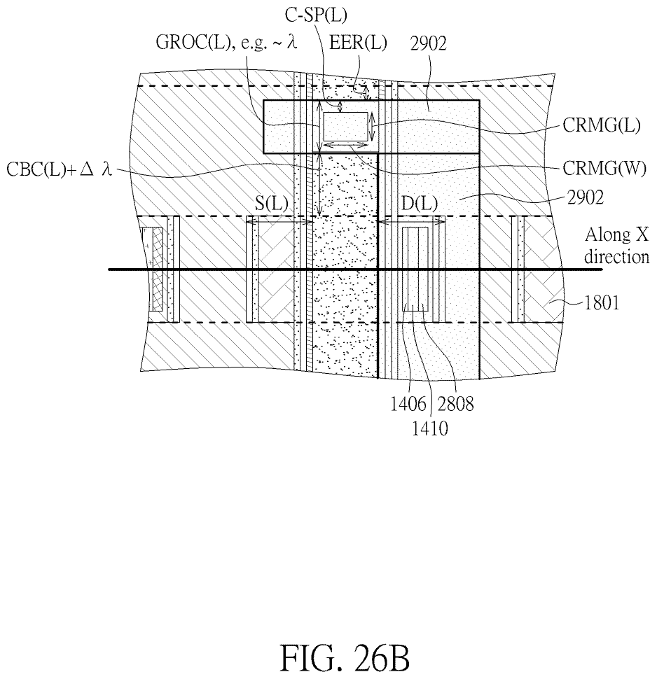

Similar to FIG. 24A, FIG. 24B, FIG. 26A, FIG. 26B show both cross-section and top view of the NuGAAT formation at the stage of forming contact openings on the drain regions and the gate structure for the extension connection crossover to the drain regions, respectively. However, as shown in FIG. 26A, the drain and source regions in the NuGAAT could be formed by Merged Semiconductor-Junction & Metal-connection (MSMC) structure which includes: (a) an n+ doped silicon source/drain layer (called as SDSL) formed to be abutting to the substrate 102, and (b) a core metal column (CMC) formed inside the source region (i.e. core metal column 2806) and the drain region (i.e. core metal column 2808), respectively, as a major connection path which has a high-conductance ohmic contact to the n+ silicon.

This CMC (i.e. the core metal column 2806 and the core metal column 2808) has its three sidewalls isolated by deep oxide isolation (DOI, that is, the STI-oxide-2 layer 1002), wherein the deep oxide isolation is commonly used for Tri-gate or FinFET structure and for separating NMOS transistor from neighboring transistors, and its fourth sidewall facing the channel region having a composite interface composed of oxide guard layer (OGL) 2810/2812 and SDSL which is directly in touch with LDD 2814/2816.

Furthermore, as shown in FIG. 26A, the bottom wall of the core metal column 2808 in the drain region is also guarded by the SiOCN layer 1404 and the oxide-3B layer 1402, such that the core metal column 2808 in the drain region is electrically isolated from the substrate 102 completely. The top of the core metal column 2808 in the drain region then could be designed for receiving the metal-1 interconnection (metal-1 layer 2902) to connect the gate structure on the extension region to the drain region by a photolithographic masking technique. How to form Merged Semiconductor-Junction & Metal-Connection (MSMC) structure in source and drain is already disclosed in U.S. provisional application No. 63/021,099 filed on May 7, 2020 (Title: Merged Semiconductor-Junction & Metal-Connection Structures for Transistors to CMOS Circuits inside Silicon Substrate) by the same inventor in the present invention. All contents of the aforesaid US provisional application are incorporated by reference herein. On the other hand, the top of the source region is covered by the SOD 1801 to avoid further metal-1 interconnection. In addition, FIG. 26B is the top view of the NuGAAT shown in FIG. 26A.

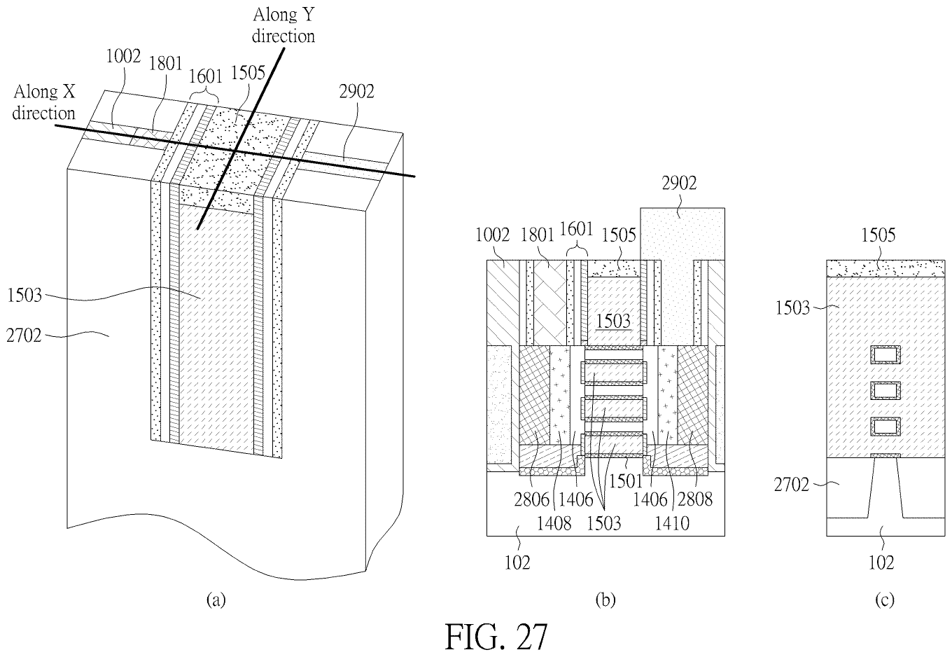

As mentioned, the top of the composite STI layer is higher than the HSS. Moreover, the sidewalls of source/drain regions will be limited by the composite STI, such that the limited sidewalls of the source/drain regions is vertical or substantially vertical. The NuGAAT structure with the 3D modeling structure of the present invention is shown in FIG. 27(a), wherein FIG. 27(b) shows a cross-section view along an X direction shown in FIG. 27(a) and FIG. 27(c) shows a cross-section view along a Y direction shown in FIG. 27(a). In addition, as shown in FIG. 27(a), an inter-layer dielectric (ILD) portion 2702 of the composite STI layer is above the STI portion (not shown in FIG. 27(a)) of the composite STI layer. The ILD portion 2702 surrounds the source/drain regions (such as sidewalls of the source/drain regions), and could also cover the top of the source/drain regions and surrounds the gate structure. The top of the STI portion is not higher than the bottom of the source/drain region. Moreover, the HTC material could be within the ILD portion, within the STI portion, or within both ILD portion and STI portion.

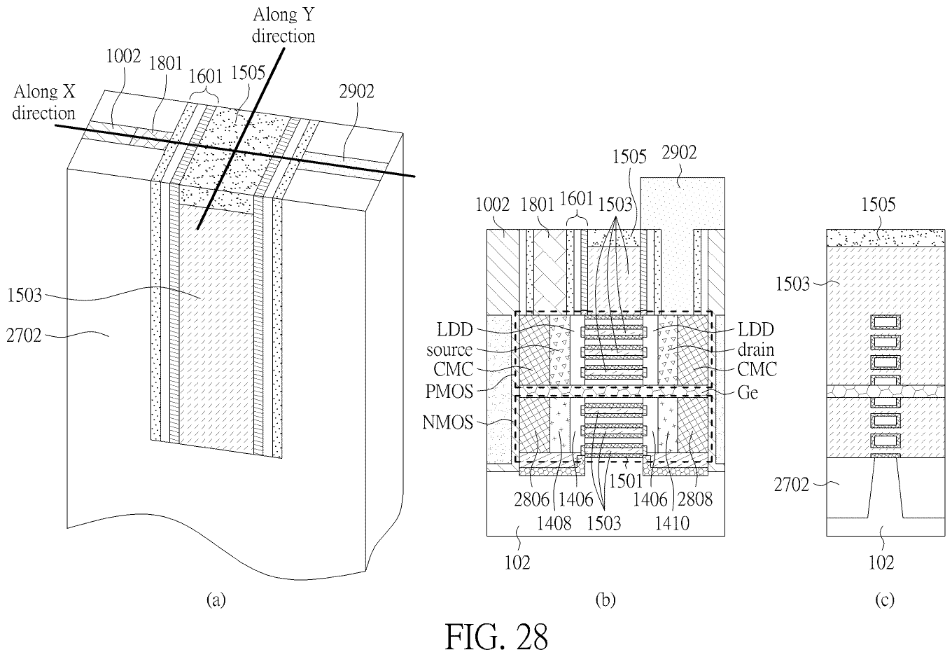

Similarly, the present invention can also be applied to the CFET structure which could be named as new complementary field-effect transistor (NuCFET). In another embodiment of the present invention, the 3D modeling structure for NuCFET is shown in FIG. 28(a), wherein FIG. 28(b) shows a cross-section view along an X direction shown in FIG. 28(a) and FIG. 28(c) shows a cross-section view along a Y direction shown in FIG. 28(a). As shown in FIG. 28(a), the composite STI layer raised above the HSS includes the inter-layer dielectric (ILD) portion 2702 above the STI portion (not shown in FIG. 28), just like previously described. The ILD portion 2702 surrounds the source/drain regions (such as sidewalls of the source/drain regions), and could also cover the top of the source/drain regions and surrounds the gate structure. The top of the STI portion is not higher than the bottom of the source/drain region. Moreover, the HTC material could be within the ILD portion, within the STI portion, or within both ILD portion and STI portion. Of course, the present invention with the previously mentioned composite STI layer (higher than HSS) could be applied in FinFET structure as well.

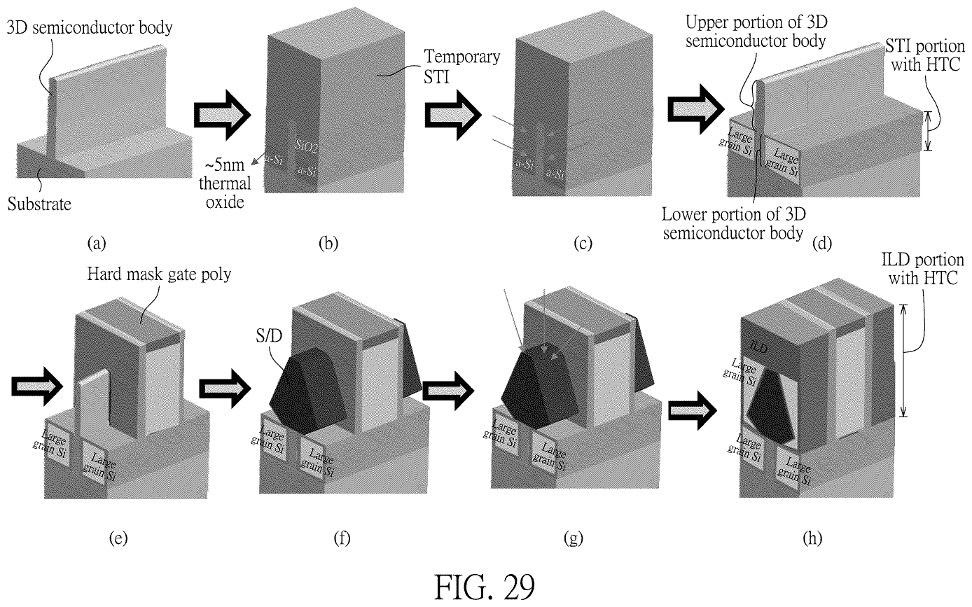

In another embodiment, a new transistor structure (such as FinFET, GAA, CFET, etc.) with HTC material in the isolation region is presented. In FIG. 29, the advanced semiconductor manufacturing processes are proposed based on conventional processes with additional improvement. As shown in FIG. 29(a), the semiconductor manufacturing process begins with 3D (three-dimensional) semiconductor body (such as fin structure, or fin structure with Si/SiGe multiple layers for GAA/CFET structure) formation using SAQP (Self-Aligned Quadruple Patterning) mandrel processing to establish precise 3D architectures. The 3D semiconductor body is extended upward from the semiconductor substrate. As shown in FIG. 29(b), a liner oxide layer is first deposited over the 3D semiconductor body, then amorphous silicon is deposited over the liner oxide, thereafter isolation material (such as oxide) is further deposited to cover the amorphous silicon to form a temporary STI region. Furthermore, as shown in FIG. 29(c), well and punch-through implementation creates the necessary device regions. As shown in FIG. 29(d), thermal annealing is performed for amorphous silicon recrystallization into large grain Si or undoped polysilicon. This large grain Si is a kind of HTC material as compared with the conventional SiO₂ in the STI region. In one example, the size of one grain in the large grain Si is greater than 0.1 μm, 0.3 μm, 0.5 μm or even greater than 1 μm, depending on the area of the temporary STI region and/or the annealing process. On the other hand, due to the limitation of the height of the temporary STI region, the vertical size of the Si grain is between 10 nm˜100 nm (such as 30-40 nm), depending on the depth of the large grain Si region in the temporary STI region. In another embodiment, the deposition of amorphous silicon could be replaced by deposition of polysilicon, such that the thermal annealing process could be omitted. Then, the active region (corresponding to upper portion of 3D semiconductor body) is revealed through etching down a portion of the temporary STI region, such that a STI region with HTC material (large grain Si) is formed. This STI region surrounds a lower portion of the 3D semiconductor body.

Moreover, as shown in FIG. 29(e), the manufacturing process continues with dummy poly gate and hardmask formation to enable subsequent replacement processes. As shown in FIG. 29(f), the exposed active region not covered by the dummy poly gate and hardmask is etched down to reveal the sidewalls and bottom walls of semiconductor (Si) surface, and then enhanced epitaxy growth for the source/drain region based on the sidewall and bottom walls of Si surface is performed to provide improved selectivity and crystal quality. In FIG. 29(f), the shape of the source/drain region is just similar to a diamond shape. As shown in FIG. 29(g), followed by source/drain implantation with optimized doping profiles. As shown in FIG. 29(h), liner oxide is first deposited to cover the exposed source/drain region, then amorphous silicon is deposited over the liner oxide, and isolation material (such as conventional ILD material) is further deposited to cover the amorphous silicon, and thereafter thermal annealing is performed for amorphous silicon recrystallization into large grain Si or polysilicon to form ILD region or portion with HTC material. In another embodiment, the deposition of amorphous silicon could be replaced by deposition of polysilicon, such that the thermal annealing process could be omitted. Of course, in another embodiment, the large grain Si or polysilicon could be replaced by other HTC material, such as high bandgap material or isolation material, as previously mentioned.

As shown in FIG. 29, the key difference between the conventional 3D transistor device and the present invention is that the STI region and/or the ILD region of the present invention could include HTC material for heat dissipation. The HTC material in the ILD region could surround at least three sides of the source/drain regions (see FIG. 29(h)), and the top of the HTC material in the ILD region could be leveled up to the top of the source/drain regions. The top of the HTC material in the STI region could be leveled up to the bottom of the source/drain regions. These modifications collectively deliver superior device performance, better manufacturing yield, and enhanced reliability for next-generation FinFET (Fin Field Effect Transistor), GAAFET (Gate All Around Field Effect Transistor), and CFET (Complementary Field Effect Transistor) technologies used in advanced semiconductor applications.

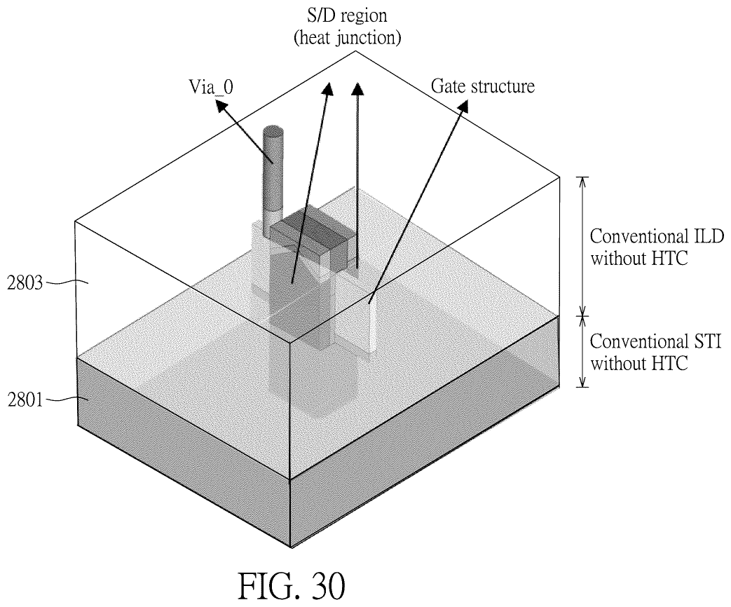

The 3D modeling structure of the conventional GAAT structure shown in FIG. 30 includes the STI region and ILD (inter-layer dielectric) region as an electrical isolation between adjacent transistors. As shown in FIG. 30, in the conventional GAAT structure, the STI region 2801 is located beneath the entire device structure or beneath the source/drain region, and the ILD region 2803 above the STI region 2801 surrounds the source/drain regions (including top surface and sidewalls of the source/drain regions) and the gate structure. The top of the ILD layer 2803 could be higher than the top of the gate structure. As shown in FIG. 30, due to high electric fields at the source/drain junction that accelerate carriers and create heat, the heat generated from the source/drain junction needs to be dissipated. Because in the conventional 3D transistor structure, the STI layer 2801 and the ILD layer 2803 surrounding the heat junction are not made of (or do not include) high thermal conductivity material, the heat from the source/drain junction could be high, resulting in the heat accumulated from the S/D junction difficult to be dissipated and the heat spot in the S/D junction being present.

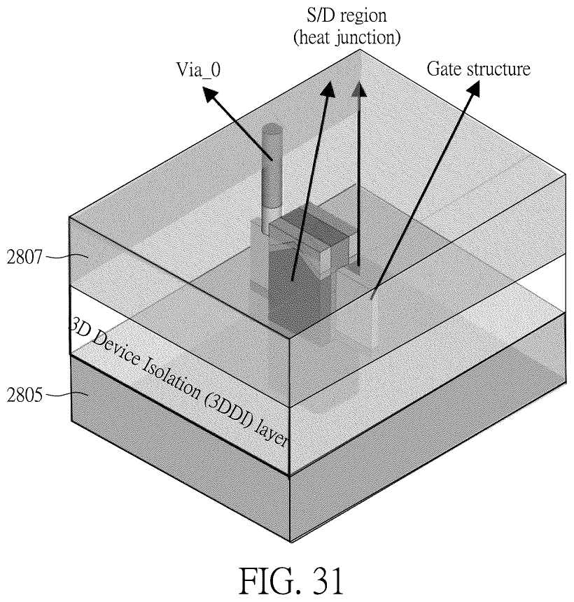

On the other hand, FIG. 31 is a 3D perspective view of the GAAT structure according to the present invention, wherein most of the ILD region 2807 is replaced with the HTC material. This HTC material could be named as 3D Device Isolation layer (3DDI). The 3D device isolation layer is an isolation or dielectric material, but its thermal conductivity is higher than the thermal conductivity of SiO₂. In one example, the 3D device isolation layer surrounds the source/drain (S/D) regions, such as covering sidewalls of the source/drain regions and/or the top of the source/drain regions. In another example, the top of the 3D device isolation layer could be as high as the top of the gate structure. Of course, it is possible that most of the STI region 2805 could be replaced with the HTC material or 3DDI layer.

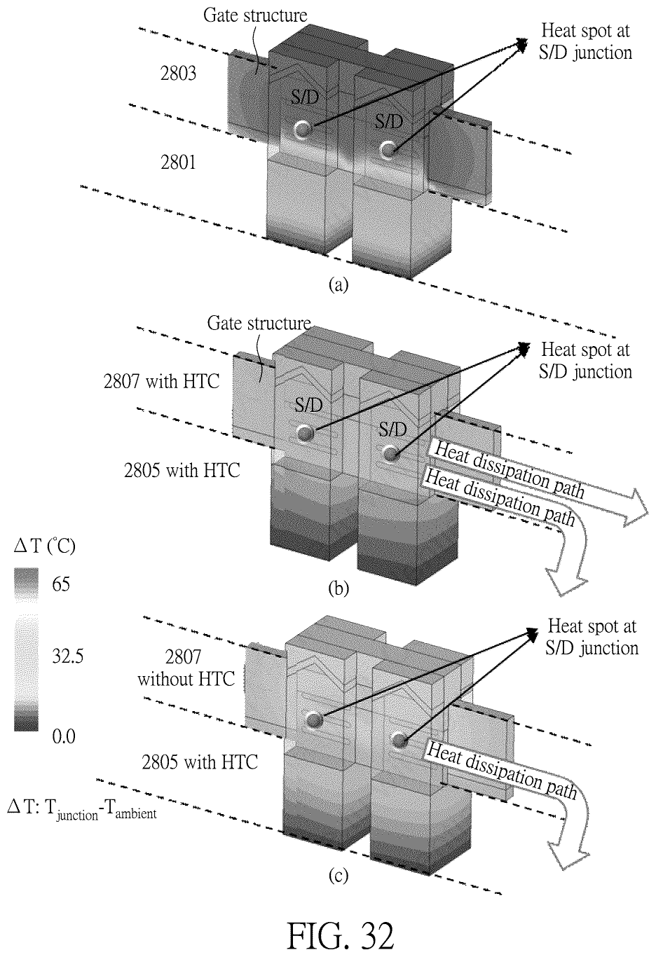

FIG. 32(a) is the thermal simulation result for the conventional GAAT structure shown in FIG. 30. To optimize the heat dissipation path, there are two cooling options for the GAAT structure of the present invention shown in FIG. 32(b) (named as “option A”) and FIG. 32(c) (named as “option B”), respectively. In FIG. 32(c), the STI layer 2805 below the S/D junction and the gate structure is made of (or includes) HTC material, and can make one heat dissipation path from the S/D junction. However, the ILD layer 2807 in option B is still not made of (or does not include) HTC material. On the other hand, in FIG. 32(b), both the STI layer 2805 and the ILD layer 2807 (most of the ILD layer 2807 or all ILD layer 2807) are made of (or include) HTC material, which leads to the lowest junction temperature result due to two heat dissipation paths from S/D junction through (1) the gate structure to the high thermal conductivity STI layer 2805 and (2) the gate structure to the high thermal conductivity layer in the ILD layer 2807.

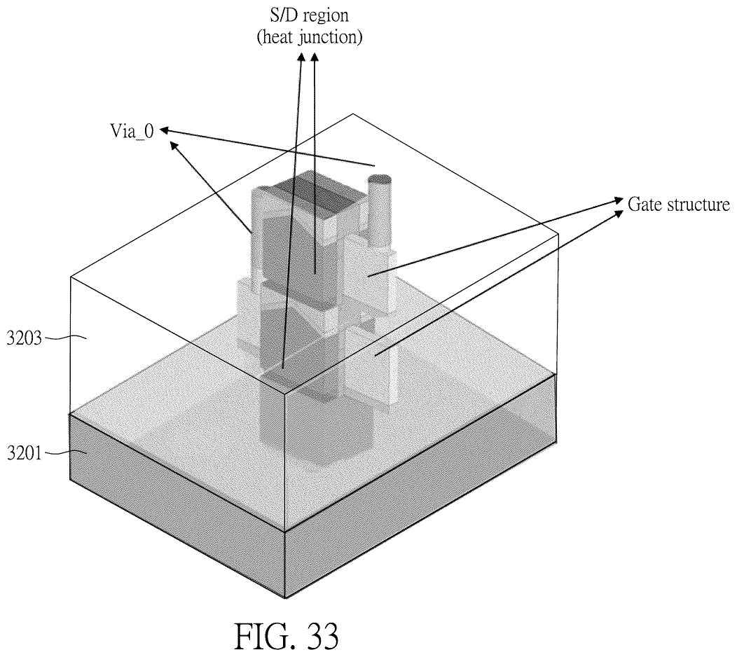

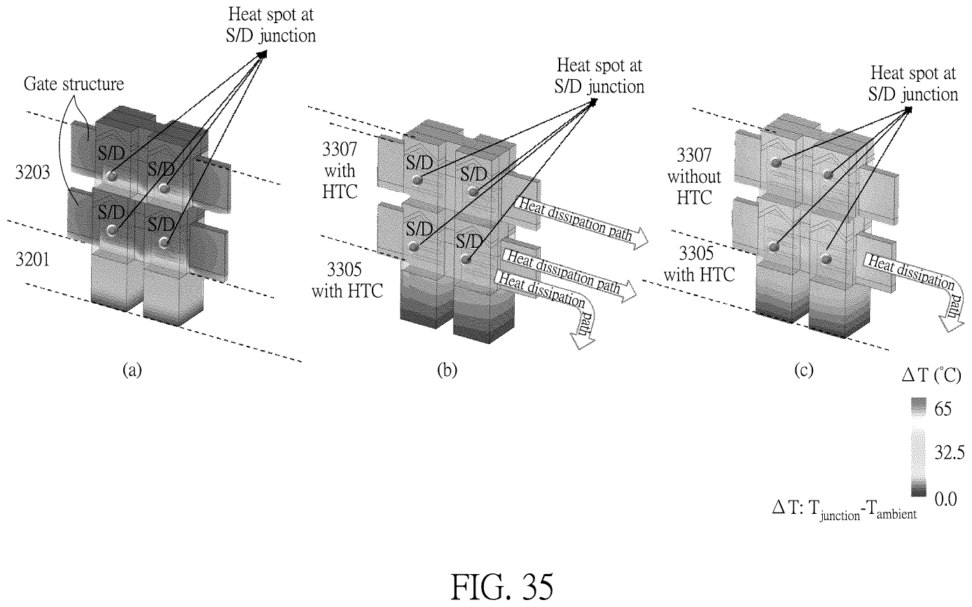

Similarly, the 3D modeling structure of the conventional CFET structure shown in FIG. 33 also includes the STI and ILD (inter-layer dielectric) region as an electrical isolation between adjacent transistor and the gate structure from the source region and the drain region. As shown in FIG. 33, in the conventional CFET structure, the STI region 3201 locates beneath the entire device structure, and the ILD region 3203 above the STI region 3201 surrounds the source/drain regions (including top surface and sidewalls of the source/drain regions) and the gate structure. The top of the ILD region 3203 could be higher than the top of the gate structure. As shown in FIG. 33, due to high electric fields at S/D junction extension that accelerate carriers and create heat, the heat generated from the S/D junction needs to be dissipated. Therefore, as shown in FIG. 35(a), because the STI region 3201 and the ILD region 3203 surrounding the heat junction are not made of (or do not include) high thermal conductivity material, the heat from S/D junction could be high, resulting in the heat accumulated from the S/D junction being difficult to be dissipated and the heat spot in the S/D junction being present.

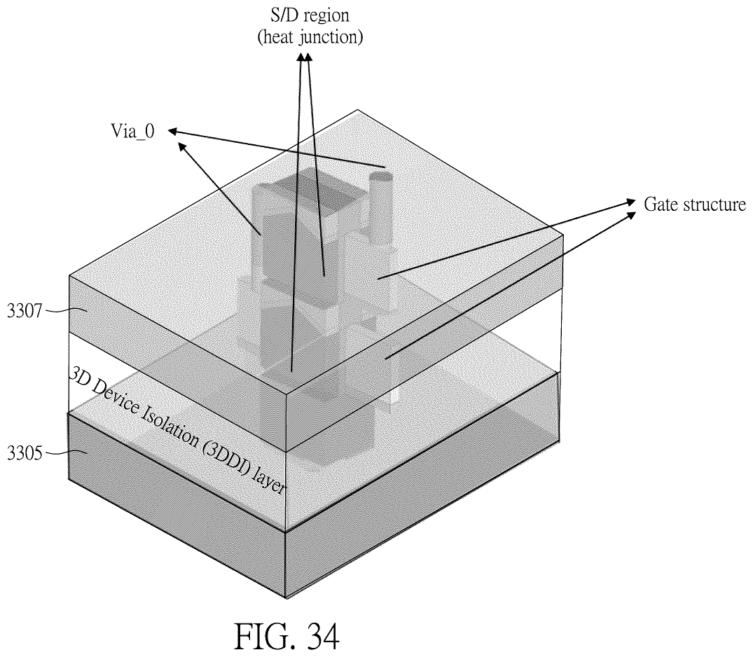

On the other hand, FIG. 34 is a 3D perspective view of the CFET structure according to the present invention, wherein most of the ILD region 3307 is replaced with the HTC material or 3D Device Isolation layer (3DDI). In one example, the 3D device isolation layer surrounds the source/drain (S/D) regions of the CFET, such as covering sidewalls of the source/drain regions and/or the top of the source/drain regions. In another example, the top of the 3D device isolation layer could be as high as the top of the gate structure. Of course, it is possible that most of the STI region 3305 could be replaced with the HTC material or 3DDI layer.

In FIG. 35(c) for one example of the CFET structure of the present invention, the STI layer 3305 below the S/D regions and the gate structure for both N/P FETs is made of (or includes) HTC material, and makes one heat dissipation path from S/D junction for NFETs or PFETs. However, the ILD layer 3307 is still not made of (or does not include) HTC material. Furthermore, as shown in FIG. 35(b) for another example of the CFET structure of the present invention, both the STI region 3305 and the ILD region 3307 (most of the ILD layer 3307 or all ILD layer 3307) are made of (or include) HTC material, which leads to the lowest junction temperature result due to two heat dissipation paths from the S/D junction through (1) the gate structure to the high thermal conductivity STI layer 3305 and (2) the gate structure to the high thermal conductivity layer (or 3DDI layer) in the ILD layer 3307. In one example, the 3DDI layer surrounds the source/drain (S/D) regions, such as covering top surface and sidewalls of source/drain. In another example, the top of the 3D device isolation layer could be as high as the top of the gate structure.

In summary, the present invention proposes a new 3D transistor structure (such as FinFET, GAA transistor, or CFET structure) resulted by making the first metal interconnection (metal-1 layer) directly connecting the gate structure, the source and drain regions through self-aligned miniaturized contacts without using a conventional contact-hole-opening mask and/or a Metal-0 translation layer for metal-1 connections. The construction also includes: (1) raised shallow trench isolation (STI); (2) self-construction semiconductor/metal junction & landing pad; (3) self-construction underground insulator; (4) damascene gate process. Moreover, the raised STI region and the composite spacer for the gate structure are provided to surround the 3D transistor structure and a high thermal conductivity layer is within the STI region for efficient heat dissipation. Furthermore, in another 3D transistor structure according to the present invention, the STI region and/or the ILD region include HTC material, which reduces S/D junction temperature.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A transistor structure comprising:
a semiconductor substrate with a three-dimensional (3D) semiconductor body and a horizontal semiconductor surface;
a shallow trench isolation (STI) portion surrounding a lower portion of the 3D semiconductor body;
a gate region crossing over an upper portion of the 3D semiconductor body;
a first conductive region electrically coupled to a channel region within the upper portion of the 3D semiconductor body; and
an inter-layer dielectric (ILD) portion over the STI portion and surrounding the first conductive region;
wherein a high thermal conductivity (HTC) material is deposited within the STI portion and/or the ILD portion, and a thermal conductivity of the HTC material is higher than that of SiO₂.

2. The transistor structure in claim 1, wherein the HTC material is within the ILD portion and surrounds at least three sidewalls of the first conductive region.

3. The transistor structure in claim 1, wherein the HTC material is within the ILD portion, a top surface of the ILD portion is higher than a top surface of the first conductive region, and a top surface of the HTC material is close to the top surface of the first conductive region.

4. The transistor structure in claim 1, wherein the HTC material is within the ILD portion, and the ILD portion further comprises a dielectric isolation layer surrounding the HTC material.

5. The transistor structure in claim 1, wherein the HTC material is within the ILD portion, and the HTC material comprises Si, and a grain size of the Si is greater than 0.5 μm.

6. The transistor structure in claim 1, wherein the HTC material is within the ILD portion, the HTC material comprises large grain Si, and the ILD portion further comprises an oxide layer surrounding the large grain Si.

7. The transistor structure in claim 1, wherein the HTC material is within the STI portion, a top surface of the STI portion is close to a bottom surface of the first conductive region, and the STI portion further comprises a dielectric isolation layer surrounding the HTC material.

8. The transistor structure in claim 7, wherein a shape of the first conductive region is a diamond shape.

9. The transistor structure in claim 8, wherein the HTC material comprises Si, and a grain size of the Si is greater than 0.5 μm.

10. The transistor structure in claim 8, wherein the HTC material comprises large grain Si, and the ILD portion further comprises an oxide layer surrounding the large grain Si.

11. The transistor structure in claim 1, wherein both the STI portion and the ILD portion comprises the HTC material, and there is a dielectric isolation layer between the HTC material of the STI portion and the HTC material of the ILD portion.

12. The transistor structure in claim 1, wherein the HTC material of the ILD portion and surrounds at least three sidewalls of the first conductive region, a top surface of the HTC material of the STI portion is close to a bottom surface of the first conductive region, and a shape of the first conductive region is a diamond shape.

13. The transistor structure in claim 1, wherein the transistor structure is a FinFET, GAA, or CFET transistor structure.

14. A transistor structure comprising:
a semiconductor substrate with an active region and a horizontal semiconductor surface;
a channel region within the active region;
a gate region crossing over the active region and surrounding the channel region, the gate region including a gate extension portion;
a composite shallow trench isolation (STI) region surrounding the active region, wherein the composite STI region comprises a first high thermal conductivity (HTC) material and a dielectric isolation layer surrounding the HTC material, and a thermal conductivity of the first HTC material is higher than that of SiO₂; and
a first conductive region electrically coupled to the channel region;
wherein a top surface of the composite STI region is higher than the horizontal semiconductor surface.

15. The transistor structure in claim 14, wherein the first HTC material surrounds at least three sides of the first conductive region.

16. The transistor structure in claim 14, wherein the composite STI region is next to the first conductive region, and a top surface of the first HTC material close to or higher than a top surface of the first conductive region.

17. The transistor structure in claim 14, wherein:
the channel region comprises multiple semiconductor sheets;
the first conductive region comprises a lightly doped region derived from the multiple semiconductor sheets, a highly doped region abutting to a sidewall of the lightly doped region, and a core metal column at least abutting to a sidewall of the highly doped region; and
the transistor structure further comprises:
a trench under the horizontal semiconductor surface of the semiconductor substrate to accommodate the lightly doped region, the heavily doped region and the core metal column;
a localized isolation region under bottom surfaces of the heavily doped region and the core metal column; and
a metal connection layer covering top surfaces of the heavily doped region and the core metal column.

18. The transistor structure in claim 17, wherein the transistor structure is a GAA or CFET transistor structure.

19. The transistor structure in claim 14, wherein a bottom of the gate extension portion is lower than a bottom of the first conductive region.

20. The transistor structure in claim 14, wherein a first concave is formed to reveal the first conductive region, a second concave is formed over the gate extension portion to reveal the gate conductive region; and a metal connection layer is formed to fill both the first concave and the second concave and the metal connection layer is extended from the first concave to the second concave.

21. The transistor structure in claim 14, wherein sidewalls of the first conductive region is limited by the composite STI region, and the limited sidewalls of the first conductive region is vertical or substantially vertical.

22. The transistor structure in claim 14, wherein the HTC material comprises Si, and a grain size of the Si is greater than 0.3 μm.
